(19) United States
(12) Patent Application Publication
(10) Pub. No.: US 2012/0210190 A1
(43) Pub. Date: Aug. 16, 2012

(54) ENCODING AND DECODING USING ELASTIC CODES WITH FLEXIBLE SOURCE BLOCK MAPPING

(75) Inventors: Michael G. Luby, Berkeley, CA (US); Payam Pakzad, Mountain View, CA (US); Mohammad Amin Shokrollahi, Preverenges (CH); Mark Watson, San Francisco, CA (US); Lorenzo Vicisano, Berkeley, CA (US)

(73) Assignee: QUALCOMM INCORPORATED, San Diego, CA (US)

(21) Appl. No.: 13/025,900

(22) Filed: Feb. 11, 2011

(51) Int. Cl. H03M 13/00; G06F 11/08

(52) U.S. Cl. 714/755; 714/E11.03

(57) ABSTRACT

Data can be encoded by assigning source symbols to base blocks, assigning base blocks to source blocks and encoding each source block into encoding symbols, where at least one pair of source blocks is such they have at least one base block in common with both source blocks of the pair and at least one base block not in common with the other source block of the pair. The encoding of a source block can be independent of content of other source blocks. Decoding to recover all of a desired set of the original source symbols can be done from a set of encoding symbols from a plurality of source blocks wherein the amount of encoding symbols from the first source block is less than the amount of source data in the first source block and likewise for the second source block.

### CROSS REFERENCES

The present application for patent is related to the following co-pending U.S. patent applications, each of which is filed concurrently herewith, assigned to the assignee hereof, and expressly incorporated by reference herein:
U.S. patent application entitled “Framing for an Improved Radio Link Protocol Including FEC” by Mark Watson, et al., having Attorney Docket No. 092888U1; and
U.S. patent application entitled “Forward Error Correction Scheduling for an Improved Radio Link Protocol” by Michael G. Luby, et al., having Attorney Docket No. 092888U2.

The following issued patents are expressly incorporated by reference herein for all purposes:
U.S. Pat. No. 6,909,383 entitled “Systematic Encoding and Decoding of Chain Reaction Codes” to Shokrollahi et al. issued Jun. 21, 2005 (hereinafter “Shokrollahi-Systematic”); and
U.S. Pat. No. 6,856,263 entitled “Systems and Processes for Decoding Chain Reaction Codes Through Inactivation” to Shokrollahi et al. issued Feb. 15, 2005 (hereinafter “Shokrollahi-Inactivation”).

### BACKGROUND

1. Field

The present disclosure relates in general to methods, circuits, apparatus and computer program code for encoding data for transmission over a channel in time and/or space and decoding that data, where erasures and/or errors are expected, and more particularly to methods, circuits, apparatus and computer program code for encoding data using source blocks that overlap an can be partially or wholly coextensive with other source blocks.

2. Background

Transmission of files between a sender and a recipient over a communications channel has been the subject of much literature. Preferably, a recipient desires to receive an exact copy of data transmitted over a channel by a sender with some level of certainty. Where the channel does not have perfect fidelity (which covers most all physically realizable systems), one concern is how to deal with data lost or garbled in transmission. Lost data (erasures) are often easier to deal with than corrupted data (errors) because the recipient cannot always tell when corrupted data is data received in error. Many error correcting codes have been developed to correct for erasures and/or for errors. Typically, the particular code used is chosen based on some information about the infidelities of the channel through which the data is being transmitted and the nature of the data being transmitted. For example, where the channel is known to have long periods of infidelity, a burst error code might be best suited for that application. Where only short, infrequent errors are expected a simple parity code might be best.

In particular applications, there is a need for handling more than one level of service. For example, a broadcaster might broadcast two levels of service, wherein a device capable of receiving only one level receives an acceptable set of data and a device capable of receiving the first level and the second level uses the second level to improve on the data of the first level. An example of this is FM radio, where some devices only received the monaural signal and others received that and the stereo signal. One characteristic of this scheme is that the higher layers are not normally useful without the lower layers. For example, if a radio received the secondary, stereo signal, but not the base signal, it would not find that particularly useful, whereas if the opposite occurred, and the primary level was received but not the secondary level, at least some useful signal could be provided. For this reason, the primary level is often considered more worthy of protection relative to the secondary level. In the FM radio example, the primary signal is sent closer to baseband relative to the secondary signal to make it more robust.

Similar concepts exist in data transport and broadcast systems, where a first level of data transport is for a basic signal and a second level is for an enhanced layer. An example is H.264 Scalable Video Coding (SVC) wherein an H.264 base compliant stream is sent, along with enhancement layers. An example is a 1 megabit per second (mbps) base layer and a 1 mbps enhancement layer. In general, if a receiver is able to decode all of the base layer, the receiver can provide a useful output and if the receiver is able to decode all of the enhancement layer the receiver can provide an improved output, however if the receiver cannot decode all of the base layer, decoding the enhancement layer does not normally provide anything useful.

Forward error correction (“FEC”) is often used to enhance the ability of a receiver to recover data that is transmitted. With FEC, a transmitter, or some operation, module or device operating for the transmitter, will encode the data to be transmitted such that the receiver is able to recover the original data from the transmitted encoded data even in the presence of erasures and or errors.

Because of the differential in the effects of loss of one layer versus another, different coding might be used for different layers. For example, the data for a base layer might be transmitted with additional data representing FEC coding of the data in the base layer, followed by the data of the enhanced layer with additional data representing FEC coding of the data in the base layer and the enhanced layer. With this approach, the latter FEC coding can provide additional assurances that the base layer can be successfully decoded at the receiver.

While such a layered approach might be useful in certain applications, it can be quite limiting in other applications. For example, the above approach can be impractical for efficiently decoding a union of two or more layers using some encoding symbols generated from one of the layers and other encoding symbols generated from the combination of the two or more layers.

### SUMMARY

Data can be encoded by assigning source symbols to base blocks, assigning base blocks to source blocks and encoding each source block into encoding symbols, where at least one pair of source blocks is such they have at least one base block in common with both source blocks of the pair and at least one base block not in common with the other source block of the pair. The encoding of a source block can be independent of content of other source blocks. Decoding to recover all of a desired set of the original source symbols can be done from a set of encoding symbols from a plurality of source blocks wherein the amount of encoding symbols from the first source block is less than the amount of source data in the first source block and likewise for the second source block.

In specific embodiments, an encoder can encode source symbols into encoding symbols and a decoder can decode those source symbols from a suitable number of encoding symbols. The number of encoding symbols from each source block can be less than the number of source symbols in that source block and still allow for complete decoding.

In a more specific embodiment where a first source block comprises a first base block and a second source block comprises the first base block and a second base block, a decoder can recover all of the first base block and second base block from a set of encoding symbols from the first source block and a set of encoding symbols from the second source block where the amount of encoding symbols from the first source block is less than the amount of source data in the first source block, and likewise for the second source block, wherein the number of symbol operations in the decoding process is substantially smaller than the square of the number of source symbols in the second source block.

### BRIEF DESCRIPTION OF THE DRAWINGS

FIG. 1 is a block diagram of a communications system that uses elastic codes according to aspects of the present invention.

FIG. 2 is a block diagram of an example of a decoder used as part of a receiver that uses elastic codes according to aspects of the present invention.

FIG. 3 illustrates, in more detail, an encoder, which might be the encoder shown in FIG. 1, or one encoder unit in an encoder array.

FIG. 4 illustrates an example of a source block mapping according to elastic codes.

FIG. 5 illustrates an elastic code that is a prefix code and G=4.

FIG. 6 illustrates an operation with a repair symbol's block.

Attached as Appendix A is a paper presenting Slepian-Wolf type problems on an erasure channel, with a specific embodiment of an encoder/decoder system, sometimes with details of the present invention used, which also includes several special cases and alternative solutions in some practical applications, e.g., streaming. It should be understood that the specific embodiments described in Appendix A are not limiting examples of the invention and that some aspects of the invention might use the teachings of Appendix A while others might not. It should also be understood that limiting statements in Appendix A may be limiting as to requirements of specific embodiments and such limiting statements might or might not pertain the claimed inventions and, therefore, the claim language need not be limited by such limiting statements.

To facilitate understanding, identical reference numerals have been used where possible to designate identical elements that are common to the figures, except that suffixes may be added, where appropriate, to differentiate such elements. The images in the drawings are simplified for illustrative purposes and are not necessarily depicted to scale.

The appended drawings illustrate exemplary configurations of the disclosure and, as such, should not be considered as limiting the scope of the disclosure that may admit to other equally effective configurations. Correspondingly, it has been contemplated that features of some configurations may be beneficially incorporated in other configurations without further recitation.

### DETAILED DESCRIPTION

The present invention is not limited to specific types of data being transmitted. However in examples herein, it will be assumed that the data could be transmitted is represented by a sequence of one or more source symbols and that each source symbol has a particular size, sometimes measured in bits. While it is not a requirement, in these examples, the source symbol size is also the size of encoding symbols. The “size” of a symbol can be measured in bits, whether or not the symbol is actually broken into a bit stream, where a symbol has a size of M bits when the symbol is selected from an alphabet of 2^{M} symbols.

In the terminology used herein, the data to be conveyed is represented by a number of source symbols, where K is used to represent that number. In some cases, K is known in advance. For example, when the data to be conveyed is a file of unknown size and an integer multiple of the source symbol size, K would simply be the integer that is that multiple. However, it might also be the case that K is not known in advance of the transmission, or is not known until after the transmission has already started. For example, where the transmitter is transmitting a data stream as the transmitter receives the data and does not have an indication of when the data stream might end.

An encoder generates encoding symbols based on source symbols. Herein, the number of encoding symbols is often referred to as N. Where N is fixed given K, the encoding process has a code rate, r=K/N. Information theory holds that if all source symbol values are equally possible, perfect recovery of the K source symbols requires at least K encoding symbols to be received (assuming the same size for source symbols and encoding symbols) in order to fully recover the K source symbols. Thus, the code rate using FEC is usually less than one. In many instances, lower code rates allow for more redundancy and thus more reliability, but at a cost of lower bandwidth and possibly increased computing effort. Some codes require more computations per encoding symbol than others and for many applications, the computational cost of encoding and/or decoding will spell the difference between a useful implementation and an unwieldy implementation.

Each source symbol has a value and a position within the data to be transmitted and they can be stored in various places within a transmitter and/or receiver, computer-readable memory or other electronic storage, that contains a representation of the values of particular source symbols. Likewise, each encoding symbol has a value and an index, the latter being to distinguish one encoding symbol from another, and also can be represented in computer- or electronically-readable form. Thus, it should be understood that often a symbol and its physical representation can be used interchangeably in descriptions.

In a systematic encoder, the source symbols are part of the encoding symbols and the encoding symbols that are not source symbols are sometimes referred to as repair symbols, because they can be used at the decoder to “repair” damage due to losses or errors, i.e., they can help with recovery of lost source symbols. Depending on the codes used, the source symbols can be entirely recovered from the received encoding symbols which might be all repair symbols or some source symbols and some repair symbols. In a non-systematic encoder, the encoding symbols might include some of the source symbols, but it is possible that all of the encoding symbols are repair symbols. So as not to have to use separate terminology for systematic encoders and nonsystematic encoders, it should be understood that the term “source symbols” refers to symbols representing the data to be transmitted or provided to a destination, whereas the term “encoding symbols” refers to symbols generated by an encoder in order to improve the recoverability in the face of errors or losses, independent of whether those encoding symbols are source symbols or repair symbols. In some instances, the source symbols are preprocessed prior to presenting data to an encoder, in which case the input to the encoder might be referred to as “input symbols” to distinguish from source symbols. When a decoder decodes input symbols, typically an additional step is needed to get to the source symbols, which is typically the ultimate goal of the decoder.

One efficient code is a simple parity check code, but the robustness is often not sufficient. Another code that might be used is a rateless code such as the chain reaction codes described in U.S. Pat. No. 6,307,487, to Luby, which is assigned to the assignee hereof, and expressly incorporated by reference herein (hereinafter “Luby I”) and the multi-stage chain reaction as described in U.S. Pat. No. 7,068,729, to Shokrollahi et al., which is assigned to the assignee hereof, and expressly incorporated by reference herein (hereinafter “Shokrollahi I”).

As used herein, the term “file” refers to any data that is stored at one or more sources and is to be delivered as a unit to one or more destinations. Thus, a document, an image, and a file from a file server or computer storage device, are all examples of “files” that can be delivered. Files can be of known size (such as a one megabyte image stored on a hard disk) or can be of unknown size (such as a file taken from the output of a streaming source). Either way, the file is a sequence of source symbols, where each source symbol has a position in the file and a value.

The term “file” might also, as used herein, refer to other data to be transmitted that is not be organized or sequenced into a linear set of positions, but may instead represent data may have orderings in multiple dimensions, e.g., planar map data, or data that is organized along a time axis and along other axes according to priorities, such as video streaming data that is layered and has multiple layers that depend upon one another for presentation.

Transmission is the process of transmitting data from one or more senders to one or more recipients through a channel in order to deliver a file. A sender is also sometimes referred to as the transmitter. If one sender is connected to any number of recipients by a perfect channel, the received data can be an exact copy of the input file, as all the data will be received correctly. Here, we assume that the channel is not perfect, which is the case for most real-world channels. Of the many channel imperfections, two imperfections of interest are data erasure and data incompleteness (which can be treated as a special case of data erasure). Data erasure occurs when the channel loses or drops data. Data incompleteness occurs when a recipient does not start receiving data until some of the data has already passed it by, the recipient stops receiving data before transmission ends, the recipient chooses to only receive a portion of the transmitted data, and/or the recipient intermittently stops and starts again receiving data.

If a packet network is used, one or more symbol, or perhaps portions of symbols, are included in a packet for transmission and each packet is assumed to have been correctly received or not at all. A transmission can be “reliable”, in that the recipient and the sender will correspond with each other in the face of failures until the recipient satisfied with the result, or unreliable, in that the recipient has to deal with what is offered by the sender and thus can sometimes fail. With FEC, the transmitter encodes data, by providing additional information, or the like, to make up for information that might be lost in transit and the FEC encoding is typically done in advance of exact knowledge of the errors, attempting to prevent errors in advance.

In general, a communication channel is that which connects the sender and the recipient for data transmission. The communication channel could be a real-time channel, where the channel moves data from the sender to the recipient as the channel gets the data, or the communication channel might be a storage channel that stores some or all of the data in its transit from the sender to the recipient. An example of the latter is disk storage or other storage device. In that example, a program or device that generates data can be thought of as the sender, transmitting the data to a storage device. The recipient is the program or device that reads the data from the storage device. The mechanisms that the sender uses to get the data onto the storage device, the storage device itself and the mechanisms that the recipient uses to get the data from the storage device collectively form the channel. If there is a chance that those mechanisms or the storage device can lose data, then that would be treated as data erasure in the communication channel.

An “erasure code” is a code that maps a set of K source symbols to a larger (>K) set of encoding symbols with the property that the original source symbols can be recovered from some proper subsets of the encoding symbols. An encoder will operate to generate encoding symbols from the source symbols it is provided and will do so according to the erasure code it is provided or programmed to implement. If the erasure code is useful, the original source symbols (or in some cases, less than complete recovery but enough to meet the needs of the particular application) are recoverable from a subset of the encoding symbols that happened to be received at a receiver/decoder, if the subset is of size greater than or equal to the size of the source symbols (an “ideal” code), or at least this should be true with reasonably high probability. In practice, a “symbol” is usually a collection of bytes, possibly several hundred bytes, and all symbols (source and encoding) are the same size.

A “block erasure code” is an erasure code that maps one of a set of specific disjoint subsets of the source symbols (“blocks”) to each encoding symbol. When a set of encoding symbols is generated from one block, those encoding symbols can be used in combination with one another to recover that one block.

The “scope” of an encoding symbol is the block it is generated from and the block that the encoding symbol is used to decode, with other encoding symbols used in combination.

The “neighborhood set” of a given encoding symbol is the set of source symbols within the symbol's block that the encoding symbol directly depends on. The neighborhood set might be a very sparse subset of the scope of the encoding symbol. Many block erasure codes, including chain reaction codes (e.g., LT codes), LDPC codes, and multi-stage chain reaction codes (e.g., Raptor codes), use sparse techniques to generate encoding symbols for efficiency and other reasons. One example of a measurement of sparseness is the ratio of the number of symbols in the neighborhood set that an encoding symbol depends on to the number of symbols in the block. For example, where a block comprises 256 source symbols (k=256) and each encoding symbol is an XOR of between two and five of those 256 source symbols, the ratio would be between 2/256 and 5/256. Similarly, where K=1024 and each encoding symbol is a function of exactly three source symbols (i.e., each encoding symbol's neighborhood set has exactly three members), then the ratio is 3/1024.

For some codes, such as Raptor codes, encoding symbols are not generated directly from source symbols of the block, but instead from other intermediate symbols that are themselves generated from source symbols of the block. In any case, for Raptor codes, the neighborhood set can be much smaller than the size of the scope (which is equal to the number of source symbols in the block) of these encoding symbols. In these cases where efficient encoding and decoding is a concern and the resulting code construction is sparse, the neighborhood set of an encoding symbol can be much smaller than its scope, and different encoding symbols may have different neighborhood sets even when generated from the same scope.

Since the blocks of a block erasure code are disjoint, the encoding symbols generated from one block cannot be used to recover symbols from a different block because they contain no information about that other block. Typically, the design of codes, encoders and decoders for such disjoint block erasure codes behave a certain way due to the nature of the code. If the encoders/decoders were simply modified to allow for nondisjoint blocks, i.e., where the scope of a block might overlap another block's scope, encoding symbols generated from the overlapping blocks would not be usable to efficiently recover the source symbols from the unions of the blocks, i.e., the decoding process does not allow for efficient usage of the small neighborhood sets of the encoding symbols when used to decode overlapping blocks. As a consequence, the decoding efficiency of the block erasure codes when applied to decode overlapping blocks is much worse than the decoding efficiency of these codes when applied to what they were designed for, i.e., decoding disjoint blocks.

A “systematic code” is one in which the set of encoding symbols contains the source symbols themselves. In this context, a distinction might be made between source symbols and “repair symbols” where the latter refers to encoding symbols other than those that match the source symbols. Where a systematic code is used and all of the encoding symbols are received correctly, the extras (the repair symbols) are not needed at the receiver, but if some source symbols are lost or erased in transit, the repair symbols can be used to repair such a situation so that the decoder can recover the missing source symbols. A code is considered to be “nonsystematic” if the encoding symbols comprise the repair symbols and source symbols are not directly part of the encoding symbols.

With these definitions in mind, various embodiments will now be described.

### Overview of Encoders/Decoders for Elastic Codes

In an encoder, encoding symbols are generated from source symbols, input parameters, encoding rules and possibly other considerations. In the examples of block-based encoding described herein, this set of source symbols from which an encoding symbol could depend is referred to as a “source block”, or alternatively, referred to as the “scope” of the encoding symbol. Because the encoder is block-based, a given encoding symbol depends only on source symbols within one source block (and possibly other details), or alternatively, depends only on source symbols within its scope, and does not depend on source symbols outside of its source block or scope.

Block erasure codes are useful for allowing efficient encoding, and efficient decoding. For example, once a receiver successfully recovers all of the source symbols for a given source block, the receiver can halt processing of all other received encoding symbols that encode for source symbols within that source block and instead focus on encoding symbols for other source blocks.

In a simple block erasure encoder, the source data might be divided into fixed-size, contiguous and non-overlapping source blocks, i.e., each source block has the same number of source symbols, all of the source symbols in the range of the source block are adjacent in locations in the source data and each source symbol belongs to exactly one source block. However, for certain applications, such constraints may lower performance, reduce robustness, and/or add to computational effort of encoding and/or decoding.

Elastic erasure codes are different from block erasure codes in several ways. One is that elastic erasure code encoders and decoders operate more efficiently when faced with unions of overlapping blocks. For some of the elastic erasure code methods described herein, the generated encoding symbols are sparse, i.e., their neighborhood sets are much smaller than the size of their scope, and when encoding symbols generated from a combination of scopes (blocks) that overlap are used to decode the union of the scopes, the corresponding decoder process is both efficient (leverages the sparsity of the encoding symbols in the decoding process and the number of symbol operations for decoding is substantially smaller than the number of symbol operations needed to solve a dense system of equations) and has small reception overhead (the number of encoding symbols needed to recover the union of the scopes might be equal to, or not much larger than, the size of the union of the scopes). For example, the size of the neighborhood set of each encoding symbol might be the square root of K when it is generated from a block of K source symbols, i.e., when it has scope K. Then, the number of symbol operations needed to recover the union of two overlapping blocks from encoding symbols generated from those two blocks might be much smaller than the square of K′, where the union of the two blocks comprises K′ source symbols.

With the elastic erasure coding described herein, source blocks need not be fixed in size, can possibly include nonadjacent locations, as well as allowing source blocks to overlap such that a given source symbol is “enveloped” by more than one source block.

In embodiments of an encoder described below, the data to be encoded is an ordered plurality of source symbols and the encoder determines, or obtains a determination of, demarcations of “base blocks” representing source symbols such that each source symbol is covered by one base block and a determination and demarcation of source blocks, wherein a source block envelops one or more base blocks (and the source symbols in those base blocks). Where each source block envelops exactly one base block, the result is akin to a conventional block encoder. However, there are several useful and unexpected benefits in coding when the source blocks are able to overlap each other such that some base block might be in more than one source block such that two source blocks have at least one base block in their intersection and the union of the two source blocks includes more source symbols than are in either one of the source blocks.

If the encoding is such that the portion of the source data that is represented by the union of the pair of source blocks is recoverable from a combination of a first set of encoding symbols generated from the first source block of the pair and a second set of encoding symbols generated from the second source block of the pair, it can be possible to decode using fewer received symbols that might have been required if the more simple encoding process is used. In this encoding process, the resulting encoding symbols can, in some cases, be used in combination for efficient recovery of source symbols of more than one source block.

An illustration of why this is so is provided below, but first, examples of implementations will be described. It should be understood that these implementations can be done in hardware, program code executed by a processor or computer, software running on a general purpose computer, or the like.

### Elastic Code Ideal Recovery Property

For block codes, ideal recovery is the ability to recover the K source symbols of a block from any received set of K encoding symbols generated from the block. It is well-known that there are block codes with this ideal recovery property. For example, Reed-Solomon codes used as erasure codes exhibit this ideal recovery property.

A similar ideal recovery property might be defined for elastic codes. Suppose an elastic code communications system is designed such that a receiver receives some set of encoding symbols (where the channel may have caused the loss of some of the encoding symbols, so the exact set might not be specifiable at the encoder) and the receiver attempts to recover all of the original source symbols, wherein the encoding symbols are generated at the encoder from a set of overlapping scopes. The overlapping scopes are such that the received encoding symbols are generated from multiple source blocks of overlapping source symbols, wherein the scope of each received encoding symbol is one of the source blocks. In other words, encoding symbols are generated from a set of T blocks (scopes) b₁, b₂, . . . , b_{T}, wherein each encoding symbol is generated from exactly one of the T blocks (scopes).

In this context, the ideal recovery property of an elastic erasure code can be described as the ability to recover the set of T blocks from a subset, E, of received encoding symbols, for any S such that 1≦S≦T, for all subsets {i₁, . . . , iₛ}, of {1, . . . , T}, if the following holds: For all s such that 1≦s≦S, for all subsets {i₁′, . . . , iₛ′} of {i₁, . . . , iₛ}, the number of symbols in E generated from any of b_{i′}_{₁}, . . . , b_{i′}_{ₛ} is at most the size of the union of b_{i′}_{₁}, . . . , b_{i′}_{ₛ}, and the number of symbols in E generated from any of bᵢ_{₁}, . . . , bᵢ_{ₛ} is equal to the size of the union of bᵢ_{₁}, . . . , bᵢ_{ₛ}. Note that E may be a subset of the received encoding symbols, i.e., some received encoding symbols might not be considered when evaluating this ideal recovery definition to see if a particular set of blocks (scopes) are recoverable.

Ideally, recovery of a set of blocks (scopes) should be computationally efficient, e.g., the number of symbol operations that the decoding process uses might be linearly proportional to the number of source symbols in the union of the recovered scopes, as opposed to quadratic, etc.

It should be noted that, while some of the descriptions herein might describe methods and processes for elastic erasure code encoding, processing, decoding, etc. that, in some cases, achieve the ideal recovery properties described above, in other cases, only a close approximation of the ideal recovery and efficiency properties of elastic codes are achieved, while still being considered to be within the definitions of elastic erasure code encoding, processing, decoding, etc.

### System Overview

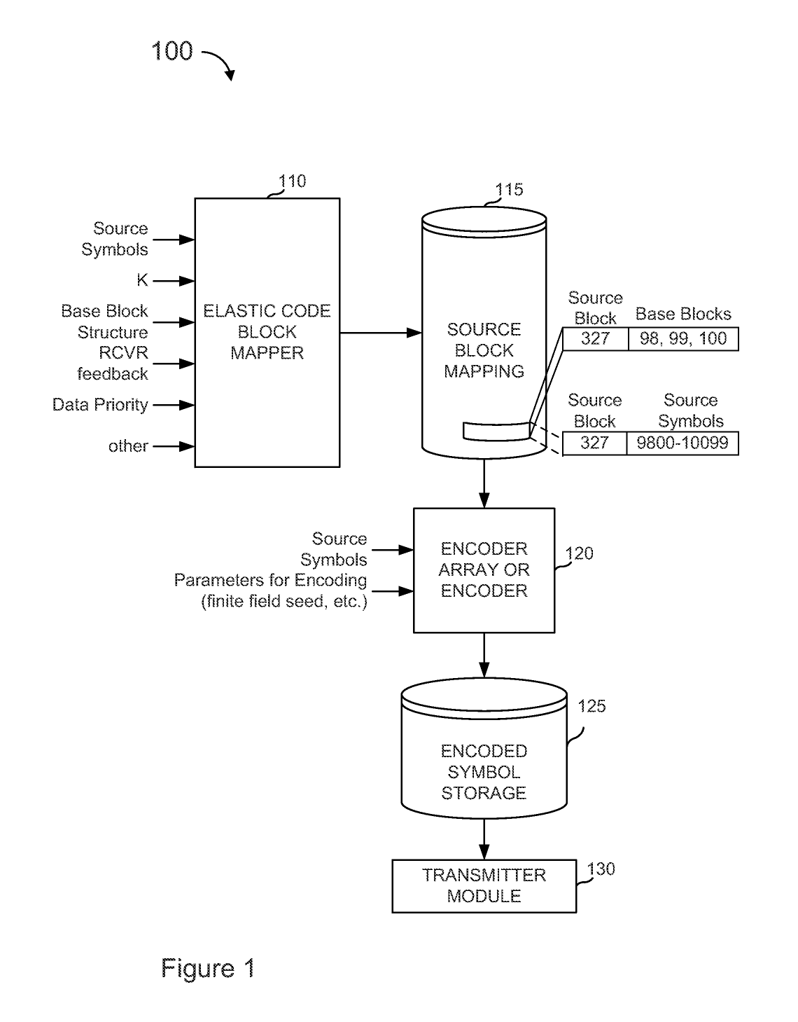

FIG. 1 is a block diagram of a communications system 100 that uses elastic codes.

In system 100, an elastic code block mapper (“mapper”) 110 generates mappings of base blocks to source blocks, and possibly the demarcations of base blocks as well. As shown in FIG. 1, communications system 100 includes mapper 110, storage 115 for source block mapping, an encoder array or encoder 120, storage 125 for encoding symbols, and transmitter module 130.

Mapper 110 determines, from various inputs and possibly a set of rules represented therein, which source blocks will correspond with which base blocks and stores the correspondences in storage 115. If this is a deterministic and repeatable process, the same process can run at a decoder to obtain this mapping, but if is it random or not entirely deterministic, information about how the mapping occurs can be sent to the destination to allow the decoder to determine the mapping.

As shown, a set of inputs (by no means required to be exhaustive) are used in this embodiment for controlling the operation of mapper 110. For example, in some embodiments, the mapping might depend on the values of the source symbols themselves, the number of source symbols (K), a base block structure provided as an input rather than generated entirely internal to mapper 110, receiver feedback, a data priority signal, or other inputs.

As an example, mapper 110 might be programmed to create source blocks with envelopes that depend on a particular indication of the base block boundaries provided as an input to mapper 110.

The source block mapping might also depend on receiver feedback. This might be useful in the case where receiver feedback is readily available to a transmitter and the receiver indicates successful reception of data. Thus, the receiver might signal to the transmitter that the receiver has received and recovered all source symbols up to an i-th symbol and mapper 110 might respond by altering source block envelopes to exclude fully recovered base blocks that came before the i-th symbol, which could save computational effort and/or storage at the transmitter as well as the receiver.

The source block mapping can depend on a data priority input that signals to mapper 110 varying data priority values for different source blocks or base blocks. An example usage of this is in the case where a transmitter is transmitting data and receives a signal that the data being transmitted is a lower priority than other data, in which case the coding and robustness can be increased for the higher priority data at the expense of the lower priority data. This would be useful, in applications such as map displays, where an end-user might move a “focus of interest” point as a map is loading, or in video applications where an end-user fast forwards or reverses during the transmission of a video sequence.

In any case, encoder array 120 uses the source block mapping along with the source symbol values and other parameters for encoding to generate encoding symbols that are stored in storage 125 for eventual transmission by transmitter module 130. Of course it should be understood that system 100 could be implemented entirely in software that reads source symbol values and other inputs and generates stored encoding symbols. Because the source block mapping is made available to the encoder array and encoding symbols can be independent of source symbols not in the source block associated with that encoding symbol, encoder array 120 can comprise a plurality of independently operating encoders that each operate on a different source block. It should also be understood that in some applications each encoding symbol is sent immediately or almost immediately after it is generated, and thus there might not be a need for storage 125, or an encoding symbol might be stored within storage 125 before it is transmitted for only a short duration of time.

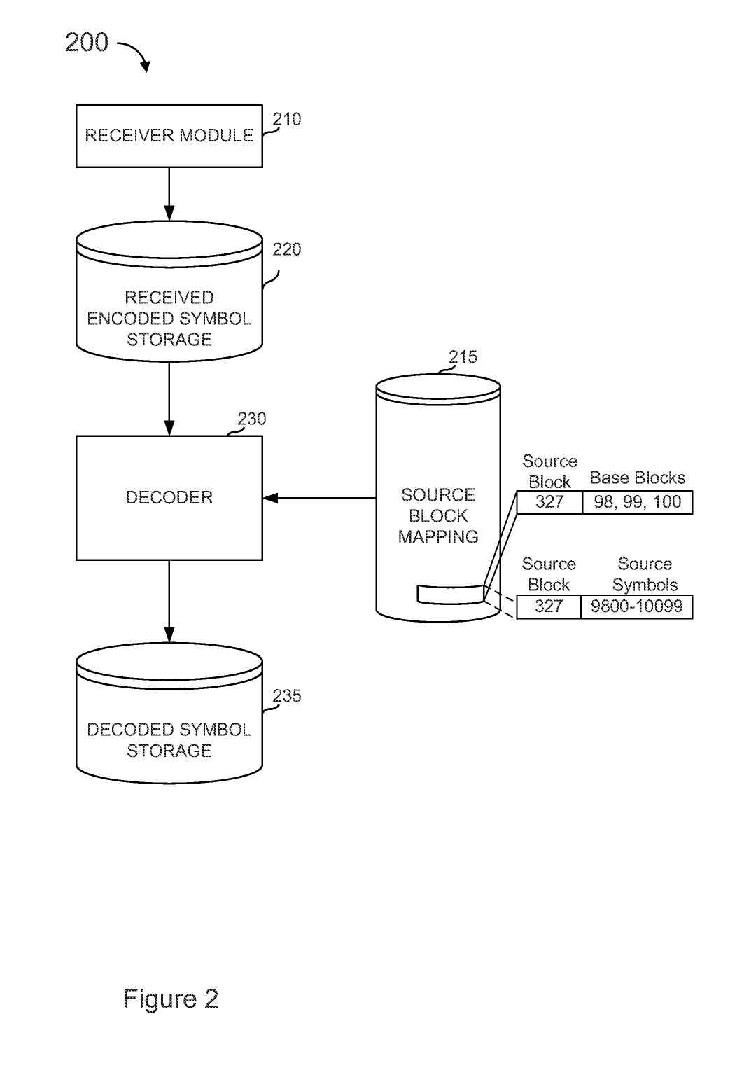

Referring now to FIG. 2, an example of a decoder used as part of a receiver at a destination is shown. As illustrated there, a receiver 200 includes a receiver module 210, storage 220 for received encoding symbols, a decoder 230, storage 235 for decoded source symbols, and a counterpart source block mapping storage 215. Not shown is any connection needed to receive information about how to create the source block mapping, if that is needed from the transmitter.

Receiver module 210 receives the signal from the transmitter, possibly including erasures, losses and/or missing data, derives the encoding symbols from the received signal and stores the encoding symbols and storage 220.

Decoder 230 can read the encoding symbols that are available, the source block mapping from storage 215 to determine which symbols can be decoded from the encoding symbols based on the mappings, the available encoding symbols and the previously decoded symbols in storage 235. The results of decoder 230 can be stored in storage 235.

It should be understood that storage 220 for received encoded symbols and storage 235 for decoded source symbols might be implemented by a common memory element, i.e., wherein decoder 230 saves the results of decoding in the same storage area as the received encoding symbols used to decode. It should also be understood from this disclosure that encoding symbols and decoded source symbols may be stored in volatile storage, such as random-access memory (RAM) or cache, especially in cases where there is a short delay between when encoding symbols first arrive and when the decoded data is to be used by other applications. In other applications, the symbols are stored in different types of memory.

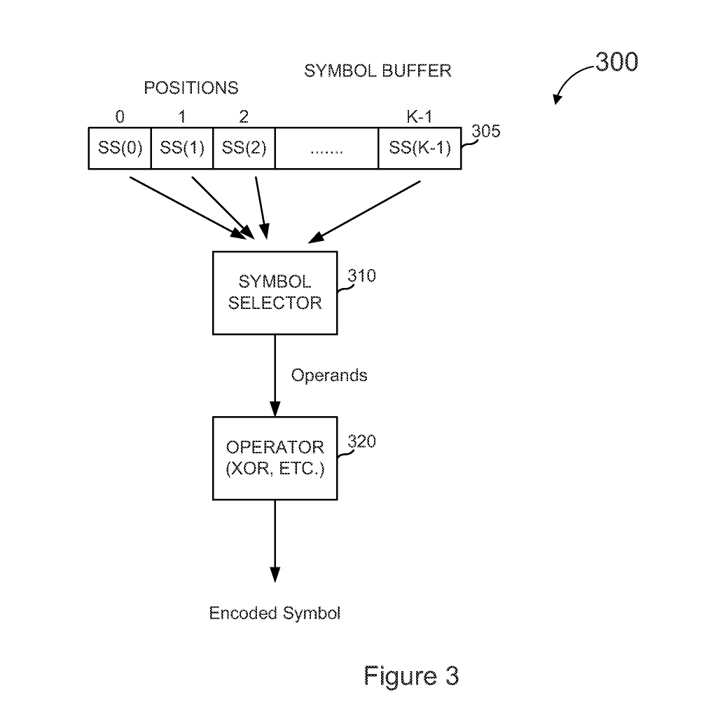

FIG. 3 illustrates in more detail an encoder 300, which might be the encoder shown in FIG. 1, or one encoder unit in an encoder array. In any case, as illustrated, encoder 300 has a symbol buffer 305 in which values of source symbols are stored. In the illustration, all K source symbols are storable at once, but it should be understood that the encoder can work equally as well with a symbol buffer that has less than all of the source symbols. For example, a given operation to generate an encoding symbol might be carried out with symbol buffer only containing one source block's worth of source symbols, or even less than an entire source block's worth of source symbols.

A symbol selector 310 selects from one to K of the source symbol positions in symbol buffer 305 and an operator 320 operates on the operands corresponding to the source symbols and thereby generates an encoding symbol. In a specific example, symbol selector 310 uses a sparse matrix to select symbols from the source block or scope of the encoding symbols being generated and operator 320 operates on the selected symbols by performing a bit-wise exclusive or (XOR) operation on the symbols to arrive at the encoding symbols. Other operations besides XOR are possible.

As used herein, the source symbols that are operands for a particular encoding symbol are referred to as that encoding symbol's “neighbors” and the set of all encoding symbols that depend on a given source symbol are referred to as that source symbol's neighborhood.

When the operation is an XOR, a source symbol that is a neighbor of an encoding symbol can be recovered from that encoding symbol if all the other neighbors source symbols of that encoding symbol are available, simply by XORing the encoding symbol and the other neighbors. This may make it possible to decode other source symbols. Other operations might have like functionality.

With the neighbor relationships known, a graph of source symbols and encoding symbols would exist to represent the encoding relationships.

### Details of Elastic Codes

Elastic codes have many advantages over either block codes or convolutional codes or network codes, and easily allow for what is coded to change based on feedback received during encoding. Block codes are limited due to the requirement that they code over an entire block of data, even though it may be advantageous to code over different parts of the data as the encoding proceeds, based on known error-conditions of the channel and/or feedback, taking into consideration that in many applications it is useful to recover the data in prefix order before all of the data can be recovered due to timing constraints, e.g., when streaming data.

Convolutional codes provide some protection to a stream of data by adding repair symbols to the stream in a predetermined patterned way, e.g., adding repair symbols to the stream at a predetermined rate based on a predetermined pattern. Convolutional codes do not allow for arbitrary source block structures, nor do they provide the flexibility to generate varying amounts of encoding symbols from different portions of the source data, and they are limited in many other ways as well, including recovery properties and the efficiency of encoding and decoding.

Network codes provide protection to data that is transmitted through a variety of intermediate receivers, and each such intermediate receiver then encodes and transmits additional encoding data based on what it received. Network codes do not provide the flexibility to determine source block structures, nor are there known efficient encoding and decoding procedures that are better than brute force, and network codes are limited in many other ways as well.

Elastic codes provide a suitable level of data protection while at the same time allowing for real-time streaming experience, i.e., introducing as little latency in the process as possible given the current error conditions due to the coding introduced to protect against error-conditions.

As explained, an elastic code is a code in which each encoding symbol may be dependent on an arbitrary subset of the source symbols. One type of the general elastic code is an elastic chord code in which the source symbols are arranged in a sequence and each encoding symbol is generated from a set of consecutive source symbols. Elastic chord codes are explained in more detail below.

Other embodiments of elastic codes are elastic codes that are also linear codes, i.e., in which each encoding symbol is a linear sum of the source symbols on which it depends and a GF(q) linear code is a linear code in which the coefficients of the source symbols in the construction of any encoding symbol are members of the finite field GF(q).

Encoders and decoders and communications systems that use the elastic codes as described herein provide a good balance of minimizing latency and bandwidth overhead.

### Elastic Code Uses for Multi-Priority Coding

Elastic codes are also useful in communications systems that need to deliver objects that comprise multiple parts for those parts may have different priorities of delivery, where the priorities are determined either statically or dynamically.

An example of static priority would be data that is partitioned into different parts to be delivered in a priority that depends on the parts, wherein different parts may be logically related or dependent on one another, in either time or some other causality dimension. In this case, the protocol might have no feedback from receiver to sender, i.e., be open-loop.

An example of dynamic priority would be a protocol that is delivering two-dimensional map information to an end user dynamically in parts as the end user focus on different parts of the map changes dynamically and unpredictably. In this case, the priority of the different parts of the map to be delivered changes based on unknown a-priori priorities that are only known based on feedback during the course of the protocol, e.g., in reaction to changing network conditions, receiver input or interest, or other inputs. For example, an end user may change their interest in terms of which next portion of the map to view based on information in their current map view and their personal inclinations and/or objectives. The map data may be partitioned into quadrants, and within each quadrant to different levels of refinement, and thus there might be a base block for each level of each quadrant, and source blocks might comprise unions of one or more base blocks, e.g., some source blocks might comprise unions of the base blocks associated with different levels of refinement within one quadrant, whereas other source blocks might comprise unions of base blocks associated with adjacent quadrants of one refinement level. This is an example of a closed-loop protocol.

### Encoders Using Elastic Erasure Coding

Encoders described herein use a novel coding that allows encoding over arbitrary subsets of data. For example, one repair symbol can encode over one set of data symbols while a second repair symbol can encode over a second set of data symbols, in such a way that the two repair symbols can recover from the loss of two source symbols in the intersections of their scopes, and each repair symbol can recover from the loss of one data symbol from the data symbols that is in their scope but not in the scope of the other repair symbol. One advantage of elastic codes is that they can provide an elastic trade-off between recovery capabilities and end-to-end latency. Another advantage of such codes is that they can be used to protect data of different priorities in such a way that the protection provided solely for the highest priority data can be combined with the data provided for the entire data to recover the entire data, even in the case when the repair provided for the highest priority data is not alone sufficient for recovery of the highest priority data.

These codes are useful in complete protocol designs in cases where there is no feedback and in cases where there is feedback within the protocol. In the case where there is feedback in the protocol, the codes can be dynamically changed based on the feedback to provide the best combination of provided protection and added latency due to the coding.

Block codes can be considered a degenerate case of using elastic codes, by having single source scopes—each source symbol belongs in only one source block. With elastic codes, source scope determination can be completely flexible, source symbols can belong to multiple source scopes, source scopes can be determined on the fly, in other than a pre-defined regular pattern, determined by underlying structure of source data, determined by transport conditions or other factors.

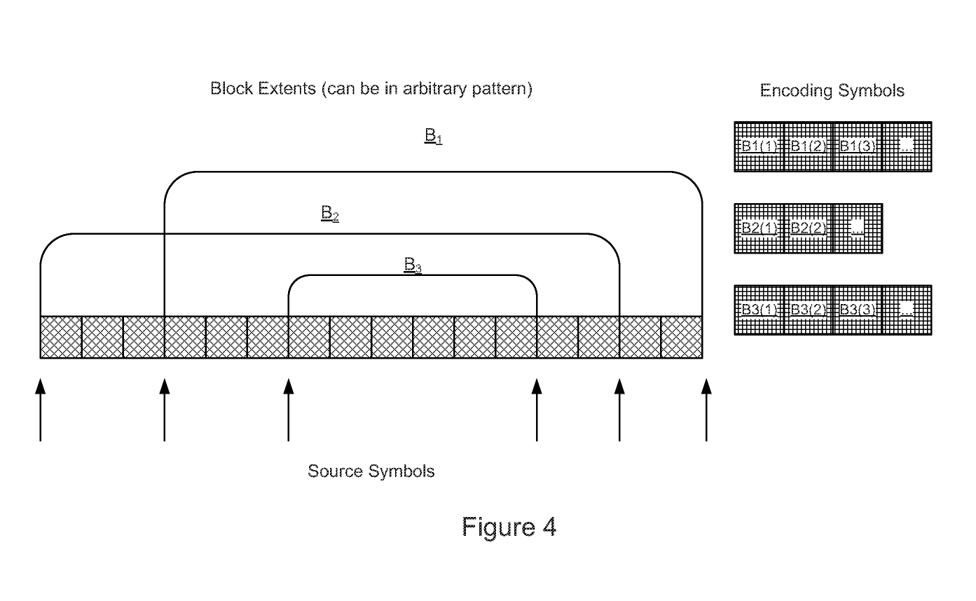

FIG. 4 illustrates an example, wherein the lower row of boxes represents source symbols and the bracing above the symbols indicates the envelope of the source blocks. In this example, there are three source blocks and thus there would be three encoded blocks, one that encodes for each one of the source blocks. In this example, if source blocks are formed from base blocks, there could be five base blocks with the base blocks demarcations indicated with arrows.

In general, encoders and decoders that use elastic codes would operate where each of the source symbols is within one base block but can be in more than one source block, or source scope, with some of the source blocks being overlapping and at least in some cases not entirely subsets of other source blocks, i.e., there are at least two source blocks that have some source symbols in common but also each have some source symbols present in one of the source blocks but not in the other. The source block is the unit from which repair symbols are generated, i.e., the scope of the repair symbols, such that repair symbols for one source block can be independent of source symbols not in that source block, thereby allowing the decoding of source symbols of a source block using encoded, received, and/or repair symbols of that source block without requiring a decoder to have access to encoded, received, or repair symbols of another source block.

The pattern of scopes of source blocks can be arbitrary, and/or can depend on the needs or requests of a destination decoder. In some implementations, source scope can be determined on-the-fly, determined by underlying structure of source data, determined by transport conditions, and/or determined by other factors. The number of repair symbols that can be generated from a given source block can be the same for each source block, or can vary. The number of repair symbols generated from a given source block may be fixed based on a code rate or may be independent of the source block, as in the case of chain reaction codes.

In the case of traditional block codes or chain reaction codes, repair symbols that are used by the decoder in combination with each other to recover source symbols are typically generated from a single source block, whereas with the elastic codes described herein, repair symbols can be generated from arbitrary parts of the source data, and from overlapping parts of the source data, and the mapping of source symbols to source blocks can be flexible.

### Selected Design Considerations

Efficient encoding and decoding is primary concern in the design of elastic codes. For example, ideal efficiency might be found in an elastic code that can decode using a number of symbol operations that is linear in the number of recovered source symbols, and thus any decoder that uses substantially fewer symbol operations for recovery than brute force methods is preferable, where typically a brute force method requires a number of symbol operations that is quadratic in the number of recovered source symbols.

Decoding with minimal reception overhead is also a goal, where “reception overhead” can be represented as the number of extra encoding symbols, beyond what is needed by a decoder, that are needed to achieve the previously described ideal recovery properties. Furthermore, guaranteed recovery, or high probability recovery, or very high likelihood recovery, or in general high reliability recovery, are preferable. In other words, in some applications, the goal need not be complete recovery.

Elastic codes are useful in a number of environments. For example with layered coding, a first set of repair symbols is provided to protect a block of higher priority data, while a second set of repair symbols protects the combination of the higher priority data block and a block of lower priority data, requiring fewer symbols at decoding and if the higher priority data block was encoded separately and the lower priority data block was encoded separately. Some known codes provide for layered coding, but often at the cost of failing to achieve efficient decoding of unions of overlapping source blocks and/or failing to achieve high reliability recovery.

The elastic window-based codes described below can achieve efficient and high reliability decoding of unions of overlapping source blocks at the same time and can also do so in the case of layered coding.

Combination with Network Coding

In another environment, network coding is used, where an origin node sends encoding of source data to intermediate nodes that may experience different loss patterns and intermediate nodes send encoding data generated from the portion of the encoding data that is received to destination nodes. The destination nodes can then recover the original source data by decoding the received encoding data received from multiple intermediate nodes. Elastic codes can be used within a network coding protocol, wherein the resulting solution provides efficient and high reliability recovery of the original source data.

### Simple Construction of Elastic Chord Codes

For the purposes of explanation, assume an encoder generates a set of repair symbols as follows, which provides a simple construction of elastic chord codes. This simple construction can be extended to provide elastic codes that are not necessarily elastic chord codes, in which case the identification of a repair symbol and its neighborhood set or scope is an extension of the identification described here. Generate an m×n matrix, A, with elements in GF(256). Denote the element in the i-th row and j-th column by Aᵢⱼ and the source symbols by Sⱼ for j=0, 1, 2, . . . . Then, for any tuple (e, l, i), where e, l and i are integers, e≧l>0 and 0≦i<m and a repair symbol R_{e,l,i} has a value as set out in Equation 1.

$${R}_{e , l , i} = {\sum }_{j = e - l + 1}^{j = e} {A}_{ij} {S}_{jmodn} \qquad ( Eqn . 1 )$$

Note that for R_{e,l,i} to be well-defined, a notion of multiplication of a symbol by an element of GF(256) and a notion of summation of symbols should be specified. In examples, herein, elements of GF(256) are represented as octets and each symbol, which can be a sequence of octets, is thought of as a sequence of elements of GF(256). Multiplication of a symbol by a field element entails multiplication of each element of the symbol by the same field element. Summation of symbols is simply the symbol formed from the concatenation of the sums of the corresponding field elements in the symbols to be summed.

The set of source symbols that appear in Equation 1 for a given repair symbol is known as the “scope” of the repair symbol, whereas the set of repair symbols that have a given source symbol appear in Equation 1 for each of those repair symbols is referred to as the “neighborhood” of the given source symbol. Thus, in this construction, the neighborhood set of a repair symbol is the same as the scope of the repair symbol.

The encoding symbols of the code then comprise the source symbols plus repair symbols, as defined herein, i.e., the constructed code is systematic.

Consider two alternative constructions for the matrix A, corresponding to two different elastic codes. For a “Random Chord Code”, the elements of A are chosen pseudo-randomly from the nonzero elements of GF(256). It should be understood herein throughout, unless otherwise indicated, where something is described as being chosen randomly, it should be assumed that pseudo-random selection is included in that description and, more generally, that random operations can be performed pseudo-randomly. For a “Cauchy Chord Code”, the elements of A are defined as shown in Equation 2, where k=255−m, and g(x) is the finite field element whose octet representation is x.

Aᵢⱼ=(g(j mod k)⊕g(255−i))⁻¹ (Eqn. 2)

Decoding Symbols from an Encoding Using a Simple Construction of Elastic Chord Codes

As well as encoding symbols themselves, the decoder has access to identifying information for each symbol, which can just be an index, i.e., for a source symbol, Sⱼ, the identifying information is the index, j. For a repair symbol, R_{e,l,i}, the identifying information is the triple (e, l, i). Of course, the decoder also has access to the matrix A.

For each received repair symbol, a decoder determines the identifying information and calculates a value for that repair symbol from Equation 1 using source symbol values if known and the zero symbol if the source symbol value is unknown. When the value so calculated is added to the received repair symbol, assuming the repair symbol was received correctly, the result is a sum over the remaining unknown source symbols in the scope or neighborhood of the repair symbol.

For simplicity, this description has a decoder programmed to attempt to recover all unknown source symbols that are in the scope of at least one received repair symbol. Upon reading this disclosure, it should be apparent how to modify the decoder to recover less than all, or all with a high probability but less than certainty, or a combination thereof.

In this example, let t be the number of unknown source symbols that are in the union of the scopes of received repair symbols and let j₀, j₁, . . . , jₜ₋₁ be the indices of these unknown source symbols. Let u be the number of received repair symbols and denote the received repair symbols (arbitrarily) as R₀, . . . , Rᵤ₋₁.

Construct the u×t matrix E with entries E_{pq}, where E_{pq} is the coefficient of source symbol Sⱼ_{_{q}} in Equation 1 for repair symbol Rₚ, or zero if Sⱼ_{_{q}} does not appear in the equation. Then, if S=(Sⱼ_{₀}, . . . , Sⱼ_{_{t−1}})^{T} is a vector of the missing source symbols and R=(R₀, . . . , Rᵤ₋₁)^{T} is a vector of the received repair symbols after applying step 1, the expression in Equation 3 will be satisfied.

R=E·S (Eqn. 3)

If E does not have rank u, then there exists a row of E that can be removed without changing the rank of E. Remove this, decrement u by one and renumber the remaining repair symbols so that Equation 3 still holds. Repeat this step until E has rank u.

If u=t, then complete decoding is possible, E is square, of full rank and therefore invertible. Since E is invertible, S can be found from E⁻¹R, and decoding is complete. If u<t, then complete decoding is not possible without reception of additional source and/or repair symbols of this subset of the source symbols or having other information about the source symbols from some other avenue.

If u<t, then let E′ be a u×u sub-matrix of E of full rank. With a suitable column permutation, E can be written as (E′ U), where U is a u×(t−u) matrix. Multiplying both sides of Equation 3 by E′⁻¹, the expression in Equation 4 can be obtained, which provides a solution for the source symbols corresponding to rows of E⁻¹R where E′⁻¹U is zero.

E′⁻¹·R=(I|E′⁻¹·U)·S (Eqn. 4)

Equation 4 allows simpler recovery of the remaining source symbols if further repair and/or source symbols are received.

Recovery of other portions of the source symbols might be possible even when recovery of all unknown source symbols that are in the scope of at least one received repair symbol is not possible. For example, it may be the case that, although some unknown source symbols are in the scope of at least one received repair symbol, there are not enough repair symbols to recover the unknown source symbols, or that some of the equations between the repair symbols and unknown source symbols are linearly dependent. In these cases, it may be possible to at least recover a smaller subset of the source symbols, using only those repair symbols with scopes that are within the smaller subset of source symbols.

### Stream Based Decoder Using Simple Construction of Elastic Chord Codes

In a “stream” mode of operation, the source symbols form a stream and repair symbols are generated over a suffix of the source symbols at the time the repair is generated. This stream based protocol uses the simple construction of the elastic chord codes described above.

At the decoder, source and repair symbols arrive one by one, possibly with some reordering and as soon as a source or repair symbol arrives, the decoder can identify whether any lost source symbol becomes decodable, then decode and deliver this source symbol to the decoder's output.

To achieve this, the decoder maintains a matrix (I|E′⁻¹·U) and updates this each time a new source or repair symbol is received according to the procedures below.

Let D denote the “decoding matrix”, (I|E′⁻¹·U). Let Dᵢⱼ denote the element at position (i,j), D_{*j} denote the j-th column of D and D_{i*} denote the i-th row of D.

In the procedures described below, the decoder performs various operations on the decoding matrix. The equivalent operations are performed on the repair symbols to effect decoding. These could be performed concurrently with the matrix operations, but in some implementations, these operations are delayed until actual source symbols are recovered in the RecoverSymbols procedure described below.

Upon receipt of a source symbol, if the source symbol is one of the missing source symbols, Sⱼ_{_{q}}, then the decoder removes the corresponding column of D. If the removed column was one of the first u columns, then the decoder identifies the repair symbol associated with the row that has a nonzero element in the removed column. The decoder then repeats the procedure described below for receipt of this repair symbol. If the removed column was not one of the first u columns, then the decoder performs the RecoverSymbols procedure described below.

Upon receipt of a repair symbol, first the decoder adds a new column to D for each source symbol that is currently unknown, within the scope of the new repair symbol and not already associated with a column of D. Next, the decoder adds a new row, D_{u*}, to D for the received repair symbol, populating this row with the coefficients from Equation 1.

For i from 0 to u−1 inclusive, the decoder replaces D_{u*} with (D_{u*}−Mᵤᵢ·D_{i*}). This step results in the first u elements of D_{u*} being eliminated (i.e., reduced to zero). If D_{u*} is nonzero after this elimination step, then the decoder performs column exchanges (if necessary) so that Dᵤᵤ is nonzero and replaces D_{u*} with (Dᵤᵤ⁻¹·D_{u*}).

For i from u−1 to 0 inclusive, the decoder replaces D_{i*} with (D_{i*}−Dᵢᵤ·D_{u*}). This step results in the elements of column u being eliminated (i.e., reduced to zero) except for row u.

The matrix is now once again in the form (I|E′⁻¹·U) and the decoder can set u:=u+1.

To perform the RecoverSymbols procedure, the decoder considers each row of E′⁻¹·U that is zero, or for all rows of D if E′⁻¹·U is empty. The source symbol whose column is nonzero in that row of D can be recovered. Recovery is achieved by performing the stored sequence of operations upon the repair symbols. Specifically, whenever the decoder replaces row D_{i*} with (D_{i*}−α·D_{j*}), it also replaces the corresponding repair symbol Rᵢ with (Rᵢ−α·Rᵢ) and whenever row D_{i*} is replaced with (α·D_{i*}), it replaces repair symbol Rᵢ with α·Rᵢ.

Note that the order in which the operations are performed is important and are the same as the order in which the matrix operations were performed.

Once the operations have been performed, then for each row of E′⁻¹·U that is zero, the corresponding repair symbol now has a value equal to that of the source symbol whose column is nonzero in that row of D and the symbol has therefore been recovered. This row and column can then be removed from D.

In some implementations, symbol operations are only performed when it has been identified that at least one symbol can be recovered. Symbol operations are performed for all rows of D but might not result in recovery of all missing symbols. The decoder therefore tracks which repair symbols have been “processed” and which have not and takes care to keep the processed symbols up-to-date as further matrix operations are performed.

A property of elastic codes, in this “stream” mode, is that dependencies may stretch indefinitely into the past and so the decoding matrix D may grow arbitrarily large. Practically, the implementation should set a limit on the size of D. In practical applications, there is often a “deadline” for the delivery of any given source symbol—i.e., a time after which the symbol is of no use to the protocol layer above or after which the layer above is told to proceed anyway without the lost symbol.

The maximum size of D may be set based on this constraint. However, it may be advantageous for the elastic code decoder to retain information that may be useful to recover a given source symbol even if that symbol will never be delivered to the application. This is because the alternative is to discard all repair symbols with a dependency on the source symbol in question and it may be the case that some of those repair symbols could be used to recover different source symbols whose deadline has not expired.

An alternative limit on the size of D is related to the total amount of information stored in the elastic code decoder. In some implementations, received source symbols are buffered in a circular buffer and symbols that have been delivered are retained, as these may be needed to interpret subsequently received repair symbols (e.g., calculating values in Equation 1 above). When a source symbol is finally discarded (due to the buffer being full) it is necessary to discard (or process) any (unprocessed) repair symbols whose scope includes that symbol. Given this fact, and a source buffer size, perhaps the matrix D should be sized to accommodate the largest number of repair symbols expected to be received whose scopes are all within the source buffer.

An alternative implementation would be to construct the matrix D only when there was a possibility of successful decoding according to the ideal recovery property described above.

### Computational Complexity

The computational complexity of the code described above is dominated by the symbol operations.

Addition of symbols can be the bitwise exclusive OR of the symbols. This can be achieved efficiently on some processors by use of wide registers (e.g., the SSE registers on CPUs following an x86 architecture), which can perform an XOR operation over 64 or 128 bits of data at a time. However, multiplication of symbols by a finite field element often must be performed byte-by-byte, as processors generally do not provide native instructions for finite field operations and therefore lookup tables must be used, meaning that each byte multiplication requires several processor instructions, including access to memory other than the data being processed.

At the encoder, Equation 1 above is used to calculate each repair symbol. This involves l symbol multiplications and l−1 symbol additions, where l is the number of source symbols in the scope of the repair symbol. If each source symbol is protected by exactly r repair symbols, then the total complexity is O(r·k) symbol operations, where k is the number of source symbols. Alternatively, if each repair symbol has a scope or neighborhood set of l source symbols, then the computational complexity per generated repair symbol is O(l) symbol operations. As used herein, the expression O( ) should be understood to be the conventional “on the order of” function.

At the decoder, there are two components to the complexity: the elimination of received source symbols and the recovery of lost source symbols. The first component is equivalent to the encoding operation, i.e., O(r·k) symbol operations. The second component corresponds to the symbol operations resulting from the inversion of the u×u matrix E, where u is the number of lost source symbols, and thus has complexity O(u²) symbol operations.

For low loss rates, u is small and therefore, if all repair symbols are used at the decoder, encoding and decoding complexity will be similar. However, since the major component of the complexity scales with the number of repair symbols, if not all repair symbols are used, then complexity should decrease.

As noted above, in an implementation, processing of repair symbols is delayed until it is known that data can be recovered. This minimizes the symbol operations and so the computational requirements of the code. However, it results in bursts of decoding activity.

An alternative implementation can smooth out the computational load by performing the elimination operations for received source symbols (using Equation 1) as symbols arrive. This results in performing elimination operations for all the repair symbols, even if they are not all used, which results in higher (but more stable) computational complexity. For this to be possible, the decoder must have information in advance about which repair symbols will be generated, which may not be possible in all applications.

### Decoding Probability

Ideally, every repair symbol is either clearly redundant because all the source symbols in its scope are already recovered or received before it is received, or is useful for recovering a lost source symbol. How frequently this is true depends on the construction of the code.

Deviation from this ideal might be detected in the decoder logic when a new received repair symbol results in a zero row being added to D after the elimination steps. Such a symbol carries no new information to the decoder and thus is discarded to avoid unnecessary processing.

In the case of the random GF(256) code implementation, this may be to be the case for roughly 1 repair symbol in 256, based on the fact that when a new random row is added to a u×u+1 matrix over GF(256) of full rank, the probability that the resulting u×u matrix does not have full rank is 1/256.

In the case of the Cauchy code implementation, when used as a block code and where the total number of source and repair symbols is less than 256, the failure probability is zero. Such a code is equivalent to a Reed-Solomon code.

### Block Mode Results

In tests of elastic chord codes used as a block code (i.e., generating a number of repair symbols all with scope equal to the full set of k source symbols), for fixed block size (k=256) and repair amount (r=8), encode speed and decode speed are about the same for varying block sizes above about 200 bytes, but below that, speed drops. This is likely because below 200 byte symbols (or some other threshold depending on conditions), the overhead of the logic required to determine the symbol operations is substantial compared to the symbol operations themselves, but for larger symbol sizes the symbol operations themselves are dominant.

In other tests, encoding and decoding speed as a function of the repair overhead (r/k) for fixed block and symbol size showed that that encoding and decoding complexity is proportional to the number of repair symbols (and so speed is proportional to 1/r).

### Stream Mode Results

When the loss rate is much less than the overhead, the average latency is low but it increases quickly as the loss rate approaches the code overhead. This is what one would expect because when the loss rate is much less than the overhead, then most losses can be recovered using a single repair symbol. As the loss rate increases, we more often encounter cases where multiple losses occur within the scope of a single repair symbol and this requires more repair symbols to be used.

Another fine-tuning that might occur is to consider the effect of varying the span of the repair symbols (the span is how many source symbols are in the scope or neighborhood set of the repair symbol), which was 256 in the examples above. Reducing the span, for a fixed overhead, reduces the number of repair symbols that protect each source symbol and so one would expect this to increase the residual error rate. However, reducing the span also reduces the computational complexity at both encoder and decoder.

Window-Based Code that is a Fountain Block Code

In many encoders and decoders, the amount of computing power and time allotted to encoding and decoding is limited. For example, where the decoder is in a battery-powered handheld device, decoding should be efficient and not require excessive computing power. One measure of the computing power needed for encoding and decoding operations is the number of symbol operations (adding two symbols, multiplying, XORing, copying, etc.) that are needed to decode a particular set of symbols. A code should be designed with this in mind. While the exact number of operations might not be known in advance, since it might vary based on which encoding symbols are received and how many encoding symbols are received, it is often possible to determine an average case or a worst case and configure designs accordingly.

This section describes a new type of fountain block code, herein called a “window-based code,” that is the basis of some of the elastic codes described further below that exhibit some aspects of efficient encoding and decoding. The window-based code as first described is a non-systematic code, but as described further below, there are methods for transforming this into a systematic code that will be apparent upon reading this disclosure. In this case, the scope of each encoding symbol is the entire block of K source symbols, but the neighborhood set of each encoding symbol is much sparser, consisting of B<<K neighbors, and the neighborhood sets of different encoding symbols are typically quite different.

Consider a block of K source symbols. The encoder works as follows. First, the encoder pads (logically or actually) the block with B zero symbols on each side to form an extended block of K+2B symbols, X₀, X₁, . . . , X_{K+2B-1}, i.e., the first B symbols and the last B symbols are zero symbols, and the middle K symbols are the source symbols. To generate an encoding symbol, the encoder randomly selects a start position, t, between 1 and K+B−1 and chooses values α₀, . . . , α_{B-1} randomly or pseudo-randomly from a suitable finite field (e.g., GF(2) or GF(256)). The encoding symbol value, ESV, is then calculated by the encoder using the formula of Equation 5, in which case the neighborhood set of the generated encoding symbol is selected among the symbols in positions t through t+B−1 in the extended block.

ESV=Σⱼ₌₀^{B-1}αⱼ·Xₜ₊ⱼ (Eqn. 5)

The decoder, upon receiving at least K encoding symbols, uses a to-and-fro sweep across the positions of the source symbols in the extended block to decode. The first sweep is from the source symbol in the first position to the source symbol in the last position of the block, matching that source symbol, s, with an encoding symbol, e, that can recover it, and eliminating dependencies on s of encoding symbols that can be used to recover source symbols in later positions, and adjusting the contribution of s to e to be simply s. The second sweep is from the source symbol in the last position to the source symbol in the first position of the block, eliminating dependencies on that source symbol s of encoding symbols used to recover source symbols in earlier positions. After a successful to-and-fro sweep, the recovered value of each source symbol is the value of the encoding symbol to which it is matched.

For the first sweep process, the decoder obtains the set, E, of all received encoding symbols. For each source symbol, s, in position i=B, . . . , B+K−1 within the extended block, the decoder selects the encoding symbol e that has the earliest neighbor end position among all encoding symbols in E that have s in their neighbor set and then matches e to s and deletes e from E. This selection is amongst those encoding symbols e for which the contribution of s to e in the current set of linear equations is non-zero, i.e., s contributes β·s to e, where β≠0. If there is no encoding symbol e to which the contribution of s is non-zero, then decoding fails, as s cannot be decoded. Once source symbol s is matched with an encoding symbol e, encoding symbol e is removed from the set E, Gaussian elimination is used to eliminate the contribution of s to all encoding symbols in E, and the contribution of s to e is adjusted to be simply s by multiplying e by the inverse of the coefficient of the contribution of s to e.

The second sweep process of the decoder works as follows. For each source symbol, s, in source position i=K−1, . . . , 0, Gaussian elimination is used to eliminate the contribution of s to all encoding symbols in E matched to source symbols in positions previous to i.

The decoding succeeds in fully recovering all the source symbols if and only if the system of linear equations defined by the received encoding symbols is of rank K, i.e., if the received encoding symbols have rank K, then the above decoding process is guaranteed to recover the K source symbols of the block.

The number of symbol operations per generated encoding symbol is B.

The reach of an encoding symbol is defined to be the set of positions within the extended block between the first position that is a neighbor of the encoding symbol and the last position that is a neighbor of the encoding symbol. In the above construction, the size of the reach of each encoding symbols is B. The number of decoding symbol operations is bounded by the sum of sizes of the reaches of the encoding symbols used for decoding. This is because, by the way the matching process described above is designed, an encoding symbol reach is never extended during the decoding process and each decoding symbol operation decreases the sum of the sizes of the encoding symbol reaches by one. This implies that the number of symbol operations for decoding the K source symbols is O(K·B).

There is a trade-off between the computational complexity of the window-based code and its recovery properties. It can be shown by a simple analysis that if B=O(K^{1/2}) and if the finite field size is chosen to be large enough, e.g., O(K), then all K source symbols of the block can be recovered with high probability from K received encoding symbols, and the failure probability decreases rapidly as a function of each additionally received encoding symbol. The recovery properties of the window-based code are similar to those of a random GF[2] code or random GF[256] code when GF[2] or GF[256] are used as the finite field, respectively, and B=O(K^{1/2}).

A similar analysis can be use to show that if B=O(ln(K/δ)/ε) then all K source symbols of the block can be recovered with probability at least 1−δ after K·(1+ε) encoding symbols have been received.

There are many variations of the window-based codes described herein, as one skilled in the art will recognize. As one example, instead of creating an extended block of K+2B symbols, instead one can generate encoding symbols directly from the K source symbols, in which case t is chosen randomly between 0 and K−1 for each encoding symbol, and then the encoding symbol value is computed as shown in Equation 6. One way to decode for this modified window-based block code is to use a decoding procedure similar to that described above, except at the beginning a consecutive set of B of the K source symbols are “inactivated”, the decoding proceeds as described previously assuming that these B inactivated source symbol values are known, a B×B system of equations between encoding symbols and the B inactivated source symbols is formed and solved, and then based on this and the results of the to-and-fro sweep, the remaining K−B source symbols are solved. Details of how this can work are described in Shokrollahi-Inactivation.

ESV=Σⱼ₌₀^{B-1}αⱼ·X_{(t+j)mod K} (Eqn. 6)

### Systematic Window-Based Block Code

The window-based codes described above are non-systematic codes. Systematic window-based codes can be constructed from these non-systematic window-based codes, wherein the efficiency and recovery properties of the so-constructed systematic codes are very similar to those of the non-systematic code from which they are constructed.

In a typical implementation, the K source symbols are placed at the positions of the first K encoding symbols generated by the non-systematic code, decoded to obtain an extended block, and then repair symbols are generated for the systematic code from the decoded extended block. Details of how this can work are described in Shokrollahi-Systematic. A simple and preferred such systematic code construction for this window-based block code is described below.

For the non-systematic window-based code described above that is a fountain block code, a preferred way to generate the first K encoding symbols in order to construct a systematic code is the following. Instead of choosing the start position t between 1 and K+B−1 for the first K encoding symbols, instead do the following. Let B′=B/2 (assume without loss of generality that B is even). Choose t=B′, B′+1, . . . , B′+K−1 for the first K encoding symbols. For the generation of the first K encoding symbols, the generation is exactly as described above, with the possible exception, if it is not already the case, that the coefficient α_{B′} is chosen to be a non-zero element of the finite field (making this coefficient non-zero ensures that the decoding process can recover the source symbol corresponding to this coefficient from this encoding symbol). By the way that these encoding symbols are constructed, it is always possible to recover the K source symbols of the block from these first K encoding symbols.

The systematic code encoding construction is the following. Place the values of the K source symbols at the positions of the first K encoding symbols generated according to the process described in the previous paragraph of the non-systematic window-based code, use the to-and-fro decoding process of the non-systematic window-based code to decode the K source symbols of the extended block, and then generate any additional repair symbols using the non-systematic window-based code applied to the extended block that contains the decoded source symbols that result from the to-and-fro decoding process.

The mapping of source symbols to encoding symbols should use a random permutation of K to ensure that losses of bursts of consecutive source symbols (and other patterns of loss) do not affect the recoverability of the extended block from any portion of encoding symbols, i.e., any pattern and mix of reception of source and repair symbols.

The systematic decoding process is the mirror image of the systematic encoding process. Received encoding symbols are used to recover the extended block using the to-and-fro decoding process of the non-systematic window-based code, and then the non-systematic window-based encoder is applied to the extended block to encode any missing source symbols, i.e., any of the first K encoding symbols that are missing.

One advantage of this approach to systematic encoding and decoding, wherein decoding occurs at the encoder and encoding occurs at the decoder, is that the systematic symbols and the repair symbols can be created using a process that is consistent across both. In fact, the portion of the encoder that generates the encoding symbols need not even be aware that K of the encoding symbols will happen to exactly match the original K source symbols.

Window-Based Code that is a Fountain Elastic Code

The window-based code fountain block code can be used as the basis for constructing a fountain elastic code that is both efficient and has good recovery properties. To simplify the description of the construction, we describe the construction when there are multiple base blocks X¹, . . . , X^{L} of equal size, i.e., each of the L basic blocks comprise K source symbols. Those skilled in the art will recognize that these constructions and methods can be extended to the case when the basic blocks are not all the same size.

As described previously, a source block may comprise the union of any non-empty subset of the L base blocks. For example, one source block may comprise the first base block and a second source block may comprise the first and second base blocks and a third source block may comprise the second and third base blocks. In some cases, some or all of the base blocks have different sizes and some or all of the source blocks have different sizes.

The encoder works as follows. First, for each base block Xⁱ, the encoder pads (logically or actually) the block with B zero symbols on each side to form an extended block of K+2B symbols X₀ⁱ, X₁ⁱ, . . . , X_{K+2B-1}ⁱ, the first B symbols and the last B symbols are zero symbols, and the middle K symbols are the source symbols of base block Xᵢ.

The encoder generates an encoding symbol for source block S as follows, where S comprises L′ base blocks, and without loss of generality assume that these are the base blocks X¹, . . . , X^{L′}. The encoder randomly selects a start position, t, between 1 and K+B−1 and for all i=1, . . . , L′, chooses values α₀ⁱ, . . . , α_{B-1}ⁱ randomly from a suitable finite field (e.g., GF(2) or GF(256)). For each i=1, . . . , L′, the encoder generates an encoding symbol value based on the same starting position t, i.e., as shown in Equation 7.

ESVⁱ=Σⱼ₌₀^{B-1}αⱼⁱ·Xₜ₊ⱼⁱ (Eqn. 7)

Then, the generated encoding symbol value ESV for the source block is simply the symbol finite field sum over i=1, . . . , L′ of ESVⁱ, i.e., as shown in Equation 8.

$$ESV = {\sum }_{i = 1 , … , {L}^{′}} {ESV}^{i} \qquad ( Eqn . 8 )$$

Suppose the decoder is used to decode a subset of the base blocks, and without loss of generality assume that these are the base blocks X¹, . . . , X^{L′}. To recover the source symbols in these L′ base blocks, the decoder can use any received encoding symbol generated from source blocks that are comprised of a union of a subset of X¹, . . . , X^{L′}. To facilitate efficient decoding, the decoder arranges a decoding matrix, wherein the rows of the matrix correspond to received encoding symbols that can be used for decoding, and wherein the columns of the matrix correspond to the extended blocks for base blocks X¹, . . . , X^{L′} arranged in the interleaved order:

X₀¹, X₀², . . . , X₀^{L′}, X₁¹, X₁², . . . , X₁^{L′}, . . . , X_{K+2B-1}, X_{K+2B-1}², . . . , X_{K+2B-1}^{L′}

Similar to the previously described to-and-fro decoder for a fountain block code, the decoder uses a to-and-fro sweep across the column positions in the above described matrix to decode. The first sweep is from the smallest column position to the largest column position of the matrix, matching the source symbol s that corresponds to that column position with an encoding symbol e that can recover it, and eliminating dependencies on s of encoding symbols that can be used to recover source symbols that correspond to later column positions, and adjusting the contribution of s to e to be simply s. The second sweep is from the largest column position to the smallest column position of the matrix from the source symbol in the last position to the source symbol in the first position of the block, eliminating dependencies on the source symbol s that corresponds to that column position of encoding symbols used to recover source symbols in earlier positions. After a successful to-and-fro sweep, the recovered value of each source symbol is the value of the encoding symbol to which it is matched.

For the first sweep process, the decoder obtains the set, E, of all received encoding symbols that can be useful for decoding base blocks X¹, . . . , X^{L′}. For each position i=L′·B, . . . , L′·(B+K)−1 that corresponds to source symbol s of one of the L′ basic blocks, the decoder selects the encoding symbol e that has the earliest neighbor end position among all encoding symbols in E that have s in their neighbor set and then matches e to s and deletes e from E. This selection is amongst those encoding symbols e for which the contribution of s to e in the current set of linear equations is non-zero, i.e., s contributes β·s to e, where β≠0. If there is no encoding symbol e to which the contribution of s is non-zero then decoding fails, as s cannot be decoded. Once source symbol s is matched with an encoding symbol e, encoding symbol e is removed from the set E, Gaussian elimination is used to eliminate the contribution of s to all encoding symbols in E, and the contribution of s to e is adjusted to be simply s by multiplying e by the inverse of the coefficient of the contribution of s to e.

The second sweep process of the decoder works as follows. For each position i=L′·(B+K)−1, . . . , L′·B that corresponds to source symbol s of one of the L′ basic blocks, Gaussian elimination is used to eliminate the contribution of s to all encoding symbols in E matched to source symbols corresponding to positions previous to i.

The decoding succeeds in fully recovering all the source symbols if and only if the system of linear equations defined by the received encoding symbols is of rank L′·K, i.e., if the received encoding symbols have rank L′·K, then the above decoding process is guaranteed to recover the L′·K source symbols of the L′ basic blocks.

The number of symbol operations per generated encoding symbol is B·V, where V is the number of basic blocks enveloped by the source block from which the encoding symbol is generated.

The reach of an encoding symbol is defined to be the set of column positions between the smallest column position that corresponds to a neighbor source symbol and the largest column position that corresponds to a neighbor source symbol in the decoding matrix. By the properties of the encoding process and the decoding matrix, the size of the reach of an encoding symbol is at most B·L′ in the decoding process described above. The number of decoding symbol operations is at most the sum of the sizes of the reaches of the encoding symbols, as by the properties of the matching process described above, the reach of encoding symbols are never extended beyond their original reach by decoding symbol operations and each decoding symbol operation decreases the sum of the sizes of the encoding symbol reaches by one. This implies that, and that the number of symbol operations for decoding the N=K·L′ source symbols in L′ basic blocks is O(N·B·L′).

There is a trade-off between the computational complexity of the window-based code and its recovery properties. It can be shown by a simple analysis that if B=O(ln(L)·K^{1/2}) and if the finite field size is chosen to be large enough, e.g., O(L·K), then all L′·K source symbols of the L′ basic blocks can be recovered with high probability if the recovery conditions of an ideal recovery elastic code described previously are satisfied by the received encoding symbols for the L′ basic blocks, and the failure probability decreases rapidly as a function of each additionally received encoding symbol. The recovery properties of the window-based code are similar to those of a random GF[2] code or random GF[256] code when GF[2] or GF[256] are used as the finite field, respectively, and B=O(ln(L)·K^{1/2}).

A similar analysis can be used to show that if B=O(ln(L·K/δ)/ε) then all L′·K source symbols of the L′ basic blocks can be recovered with probability at least 1−δ under the following conditions. Let T be the number of source blocks from which the received encoding symbols that are useful for decoding the L′ basic blocks are generated. Then, the number of received encoding symbols generated from the T source blocks should be at least L′·K·(1+ε), and for all S≦T, the number of encoding symbols generated from any set of S source blocks should be at most the number of source symbols in the union of those S source blocks.

The window-based codes described above are non-systematic elastic codes. Systematic window-based fountain elastic codes can be constructed from these non-systematic window-based codes, wherein the efficiency and recovery properties of the so-constructed systematic codes are very similar to those of the non-systematic code from which they are constructed, similar to the systematic construction described above for the window-based codes that are fountain block codes. Details of how this might work are described in Shokrollahi-Systematic.

There are many variations of the window-based codes described herein, as one skilled in the art will recognize. As one example, instead of creating an extended block of K+2B symbols for each basic block, instead one can generate encoding symbols directly from the K source symbols of each basic block that is part of the source block from which the encoding symbols is generated, in which case t is chosen randomly between 0 and K−1 for each encoding symbol, and then the encoding symbol value is computed similar to that shown in Equation 6 for each such basic block.

One way to decode for this modified window-based block code is to use a decoding procedure similar to that described above, except at the beginning a consecutive set of L′·B of the L′·K source symbols are “inactivated”, the decoding proceeds as described previously assuming that these L′·B inactivated source symbol values are known, a L′·B×L′·B system of equations between encoding symbols and the L′·B inactivated source symbols is formed and solved, and then based on this and the results of the to-and-fro sweep, the remaining L′·(K−B) source symbols are solved. Details of how this can work are described in Shokrollahi-Inactivation.

There are many other variations of the window-based code above. For example, it is possible to relax the condition that each basic block comprises the same number of source symbols. For example, during the encoding process, the value of B used for encoding each basic block can be proportional to the number of source symbols in that basic block. For example, suppose a first basic block comprises K source symbols and a second basic block comprises K′ source symbols, and let μ=K/K′ be the ratio of the sizes of the blocks. Then, the value B used for the first basic block and the corresponding value B′ used for the second basic block can satisfy: B/B′=μ. In this variation, the start position within the two basic blocks for computing the contribution of the basic blocks to an encoding symbol generated from a source block that envelopes both basic blocks might differ, for example the encoding process can choose a value φ uniformly between 0 and 1 and then use the start position t=φ·(K+B−1) for the first basic block and use the start position t′=φ·(K′+B′−1) for the second basic block (where these values are rounded up to the nearest integer position). In this variation, when forming the decoding matrix at the decoder comprising the interleaved symbols from each of the basic blocks being decoded, the interleaving can be done in such a way that the frequency of positions corresponding to the first basic block to the frequency of positions corresponding to the second basic block is in the ratio μ, e.g., if the first basic block is twice the size of the second basic block then twice as many column positions correspond to the first basic block as correspond to the second basic block, and this condition is true (modulo rounding errors) for any consecutive set of column positions within the decoding matrix.

There are many other variations as well, as one skilled in the art will recognize. For example, a sparse matrix representation of the decoding matrix can be used at the decoder instead of having to store and process the full decoding matrix. This can substantially reduce the storage and time complexity of decoding.

Other variations are possible as well. For example, the encoding may comprise a mixture of two types of encoding symbols: a majority of a first type of encoding symbols generated as described above and a minority of a second type of encoding symbols generated sparsely at random. For example the fraction of the first type of encoding symbols could be 1−K^{-1/3} and the reach of each first type encoding symbol could be B=O(K^{1/3}), and the fraction of the second type of encoding symbols could be K^{-1/3} and the number of neighbors of each second type encoding symbol could be K^{2/3}. One advantage of such a mixture of two types of encoding symbols is that the value of B used for the first type to ensure successful decoding can be substantially smaller, e.g., B=O(K^{1/3}) when two types are used as opposed to B=O(K^{1/2}) when only one type is used.

The decoding process is modified so that in a first step the to-and-fro decoding process described above is applied to the first type of encoding symbols, using inactivation decoding to inactivate source symbols whenever decoding is stuck to allow decoding to continue. Then, in a second step the inactivated source symbol values are recovered using the second type of encoding symbols, and then in a third step these solved encoding symbol values together with the results of the first step of the to-and-fro decoding are used to solve for the remaining source symbol values. The advantage of this modification is that the encoding and decoding complexity is substantially improved without degrading the recovery properties. Further variations, using more than two types of encoding symbols, are also possible to further improve the encoding and decoding complexity without degrading the recovery properties.

### Ideal Recovery Elastic Codes

This section describes elastic codes that achieve the ideal recovery elastic code properties described previously. This construction applies to the case when the source blocks satisfy the following conditions: the source symbols can be arranged into an order such that the source symbols in each source block are consecutive, and so that, for any first source block and for any second source block, the source symbols that are in the first source block but not in the second source block are either all previous to the second source block or all subsequent to the second source block, i.e., there is no first and second source blocks with some symbols of the first source block preceding the second source block and some symbols of the first source block following the second source block. For brevity, herein such codes are referred to as a No-Subset Chord Elastic code, or “NSCE code.” NSCE codes include prefix elastic codes.

It should be understood that the “construction” herein may involve mathematical concepts that can be considered in the abstract, but that such constructions are applied to a useful purpose and/or for transforming data, electrical signals or articles. For example, the construction might be performed by an encoder that seeks to encode symbols of data for transmission to a receiver/decoder that in turn will decode the encodings. Thus, inventions described herein, even where the description focuses on the mathematics, can be implemented in encoders, decoders, combinations of encoders and decoders, processes that encoder and/or decode, and can also be implemented by program code stored on computer-readable media, for use with hardware and/or software that would cause the program code to be executed and/or interpreted.

In an example construction of an NSCE code, a finite field with n^{c(n)} field elements is used, where c(n)=O(n^{C}), where C is the number of source blocks. An outline of the construction follows, and implementation should be apparent to one of ordinary skill in the art upon reading this outline. This construction can be optimized to further reduce the size of the needed finite field, at least somewhat, in some cases.

In the outline, n is the number of source symbols to be encoded and decoded, C is the number of source blocks, also called chords, used in the encoding process, c(n) is some predetermined value that is on the order of n^{C}. Since a chord is a subset (proper or not) of the n source symbols that are used in generating repair symbols and a “block” is a set of symbols generated from within the same domain, there is a one-to-one correspondence between the chords used and the blocks used. The use of these elements will now be described with reference to an encoder or a decoder, but it should be understood that similar steps might be performed by both, even if not explicitly stated.

An encoder will manage a variable, j, that can range from 1 to C and indicates a current block/chord being processed. By some logic or calculation, the encoder determines, for each block j, the number of source symbols, kⱼ, and the number of encoding symbols, nⱼ, associated with block j. The encoder can then construct a kⱼ×nⱼ Cauchy matrix, Mⱼ, for block j. The size of the field needed for the base finite field to represent the Cauchy matrices is thus the maximum of kⱼ+nⱼ over all j. Let q be the number of elements in this base field.

The encoder works over a larger field, F, with q^{D} elements, where D is on the order of q^{C}. Let ω be an element of F that is of degree D. The encoder uses (at least logically) powers of ω to alter the matrices to be used to compute the encoding symbols. For block 1 of the C blocks, the matrix M₁ is left unmodified. For block 2, the row of M₂ that corresponds to i-th source symbol is multiplied by ωⁱ. For block j, the row of Mⱼ that corresponds to i-th source symbol is multiplied by ω^{i·q(j)}, where q(j)=q^{j-2}.

Let the modified matrices be M′₁, . . . , M′_{C}. These are the matrices used to generate the encoding symbols for the C blocks. A key property of these matrices flows from an observation explained below.

Suppose a receiver has received some mix of encoding symbols generated from the various blocks. That receiver might want to determine whether the determinant of the matrix M corresponding to the source symbols and the received encoding symbols is nonzero.

Consider the bipartite graph between the received encoding symbols and the source symbols, with adjacencies defined naturally, i.e., there is an edge between an encoding symbol and a source symbol if the source symbol is part of the block from which the encoding symbol is generated. If there is a matching within this graph where all of the source symbols are matched, then the source symbols should be decodable from the received encoding symbols, i.e., the determinant of M should not be zero. Then, classify each matching by a “signature” of how the source symbols are matched to the blocks of encoding symbols, e.g., a signature of (1, 1, 3, 2, 3, 1, 2, 3) indicates that, in this matching, the first source symbol is matched to an encoding symbol in block 1, the second source symbol is matched to an encoding symbol in block 1, the third source symbol is matched to an encoding symbol in block 3, the fourth source symbol is matched to an encoding symbol in block 2, etc. Then, the matchings can be partitioned according to their signatures, and the determinant of M can be viewed as the sum of determinants of matrices defined by these signatures, where each such signature determinant corresponds to a Cauchy matrix and is thus not zero. However, the signature determinants could zero each other out.

By constructing the modified matrices M′₁, . . . , M′_{C}, a result is that there is a signature that uniquely has the largest power of ω as a coefficient of the determinant corresponding to that signature, and this implies that the determinant of M is not zero since the determinant of this unique signature cannot be zeroed out by any other determinant. This is where the chord structure of the blocks is important.

Let the first block correspond to the chord that starts (and ends) first within the source symbols, and in general, let block j correspond to the chord that is the j-th chord to start (and finish) within the source blocks. Since there are no subset chords, if any one block starts before second one, it also has to end before the second one, otherwise the second one is a subset.

Then, the decoder handles a matching wherein all of the encoding symbols for the first block are matched to a prefix of the source symbols, wherein all of the encoding symbols for the second block are matched to a next prefix of the source symbols (excluding the source symbols matched to the first block), etc. In particular, this matching will have the signature of e₁ 1's followed by e₂ 2's, followed by e₃ 3's, etc., where eᵢ is the number of encoding symbols that are to be used to decode the source symbols that were generated from block i. This matching has a signature that uniquely has the largest power of ω as a coefficient (similar to the argument used in the Theorem 1 for the two-chord case), i.e., any other signature that corresponds to a valid matching between the source and received encoding symbols will have a smaller power of ω as a coefficient. Thus, the determinant has to be nonzero.

One disadvantage with chord elastic codes occurs where subsets exist, i.e., where there is one chord contained within another chord. In such cases, a decoder cannot be guaranteed to always find a matching where the encoding symbols for each block are used greedily, i.e., use all for block 1 on the first source symbols, followed by block 2, etc., at least according to the original ordering of the source symbols.

In some cases, the source symbols can be re-ordered to obtain the non-contained chord structure. For example, if the set of chords according to an original ordering of the source symbols were such that each subsequent chord contains all of the previous chords, then the source symbols can be re-ordered so that the structure is that of a prefix code, i.e., re-order the source symbols from the inside to the out, so that the first source symbols are those inside all of the chords, followed by those source symbols inside all but the smallest chord, followed by those source symbols inside all but the smallest two chords, etc. With this re-ordering, the above constructions can be applied to obtain elastic codes with ideal recovery properties.

### Examples of Usage of Elastic Codes

In one example, the encoder/decoder are designed to deal with expected conditions, such as a round-trip time (RTT) for packets of 400 ms, a delivery rate of 1 Mbps (bits/second), and a symbol size of 128 bytes. Thus, the sender sends approximately 1000 symbols per second (1000 symbols/sec×128 bytes/symbol×8 bits/byte=1.024 Mbps). Assume moderate loss conditions of some light loss (e.g., at most 5%) and sometimes heavier loss (e.g., up to 50%).

In one approach, a repair symbol is inserted after each G source symbols, and where the maximum latency can be as little as G symbols to recover from loss, X=1/G is the fraction of repair symbols that is allowed to be sent that may not recover any source symbols. G can change based on current loss conditions, RTT and/or bandwidth.

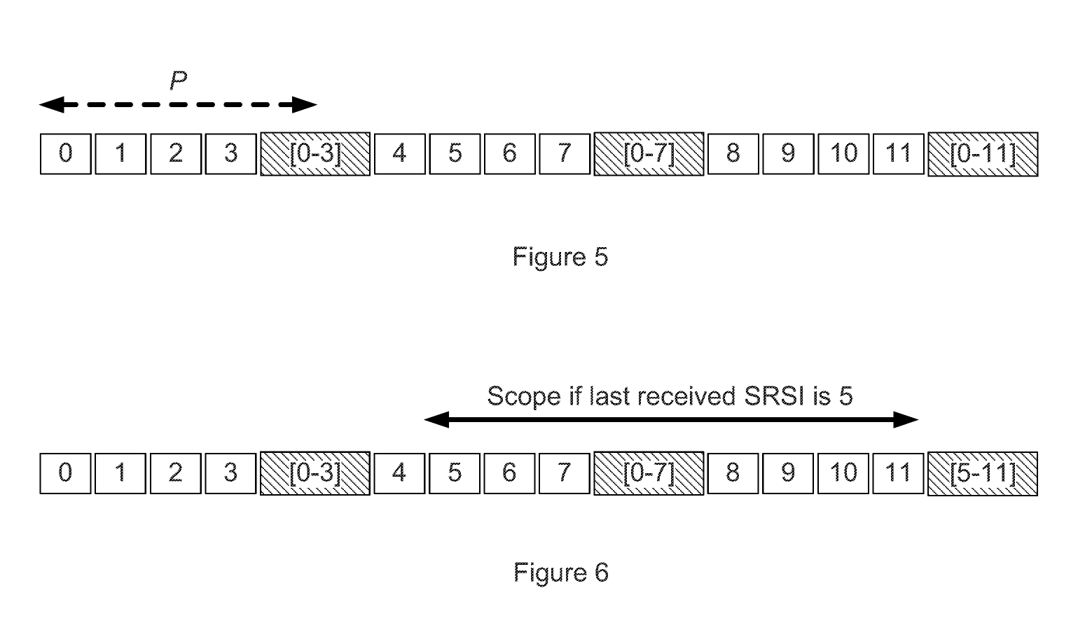

Consider the example in FIG. 5, where the elastic code is a prefix code and G=4. The source symbols are shown sequentially, and the repair symbols are shown with bracketed labels representing the source block that the repair symbol applies to.

If all losses are consecutive starting at the beginning, and one symbol is lost, then the introduced latency is at most G, whereas if two symbols are lost, then the introduced latency is at most 2×G, and if i symbols are lost, the introduced latency is at most i×G. Thus, the amount of loss affects introduced latency linearly.

Thus, if the allowable redundant overhead is limited to 5%, say, then G=20, i.e., one repair symbol is sent for each 20 source symbols. In the above example, one symbol is sent per 1 ms, so that would mean 20 ms between each repair symbol and the recovery time would be 40 ms for two lost symbols, 60 ms for three lost symbols, etc. Note that using just ARQ in these conditions, recovery time is at least 400 ms, the RTT.

In that example, a repair symbol's block is the set of all prior sent symbols. Where simple report back from the receiver are allowed, the blocks can be modified to exclude earlier source symbols that have been received or are no longer needed. An example is shown in FIG. 6, which is a variation of what is shown in FIG. 5.

In this example, assume that the encoder receives from the sender a SRSI indicator of the smallest Relevant Source Index. The SRSI can increase each time all prior source symbols are received or are no longer needed. Then, the encoder does not need to have any repair symbols depend on source symbols that have indices lower than the SRSI, which saves on computation. Typically, the SRSI is the index of the source symbol immediately following the largest prefix of already recovered source symbols. The sender then calculates scope of a repair symbol from the largest SRSI received from the receiver to the last sent index of a source symbol. This leads to exactly the same recovery properties as the no-feedback version, but lessens complexity/memory requirements at the sender and the receiver. In the example of FIG. 6, SRSI=5.

With the feedback, prefix elastic codes can be used more efficiently and feedback reduces complexity/memory requirements. When a sender gets feedback indicative of loss, it can adjust the scope of repair symbols accordingly. Thus, to combine forward error correction and reactive error correction, additional optimizations are possible. For example, the forward error correction (FEC) can be tuned so that the allowable redundant overhead is high enough to proactively recover most losses, but not too high as to introduce too much overhead, while reactive correction is for the more rare losses. Since most losses are quickly recovered using FEC, most losses are recovered without an RTT latency penalty. While reactive correction has an RTT latency penalty, its use is rarer.

### Variations

Source block mapping indicates which blocks of source symbols are used for determining values for a set of encoding symbols (which can be encoding symbols in general or more specifically repair symbols). In particular, a source block mapping might be stored in memory and indicate the extents of a plurality of base blocks and indicate which of those base blocks are “within the scope” of which source blocks. In some cases, at least one base block is in more than one source block. In many implementations, the operation of an encoder or decoder can be independent of the source block mapping, thus allowing for arbitrary source block mapping. Thus, while predefined regular patterns could be used, that is not required and in fact, source block scopes might be determined from underlying structure of source data, by transport conditions or by other factors.

In some embodiments, an encoder and decoder can apply error-correcting elastic coding rather than just elastic erasure coding. In some embodiments, layered coding is used, wherein one set of repair symbols protects a block of higher priority data and a second set of repair symbols protects the combination of the block of higher priority data and a block of lower priority data.

In some communication systems, network coding is combined with elastic codes, wherein an origin node sends encoding of source data to intermediate nodes and intermediate nodes send encoding data generated from the portion of the encoding data that the intermediate node received—the intermediate node might not get all of the source data, either by design or due to channel errors. Destination nodes then recover the original source data by decoding the received encoding data from intermediate nodes, and then decodes this again to recover the source data.

In some communication systems that use elastic codes, various applications can be supported, such as progressive downloading for file delivery/streaming when prefix of a file/stream needs to be sent before it is all available, for example. Such systems might also be used for PLP replacement or for object transport.

Those of ordinary skill in the art would further appreciate, after reading this disclosure, that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary embodiments of the invention.

The various illustrative logical blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-Ray™ disc where disks usually reproduce data magnetically, while discs reproduce data optically with lasers. Combinations of the above should also be included within the scope of computer-readable media.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

1. A method for encoding data to be transmitted over a communications channel that could possibly introduce errors or erasures, wherein source data is represented by an ordered plurality of source symbols and the source data is recoverable from encoding symbols that are transmitted, the method comprising:
identifying a base block for each symbol of the ordered plurality of source symbols, wherein the identified base block is one of a plurality of base blocks that, collectively, cover the source data to be encoded;
identifying, from a plurality of source blocks and for each base block, at least one source block that envelops that base block, wherein the plurality of source blocks includes at least one pair of source blocks that have a characteristic that there is at least one base block that is enveloped by both source blocks of the pair and at least one base block for each source block of the pair that is enveloped by that source block and not by the other source block of the pair; and
encoding each of the plurality of source blocks according to an encoding process, resulting in encoding symbols, wherein the encoding process operates on one source block to generate encoding symbols, with the encoding symbols being independent of source symbol values of source symbols from base blocks not enveloped by the one source block, wherein the encoding is such that the portion of the source data that is represented by the union of the pair of source blocks is assured to be recoverable from a combination of a first set of encoding symbols generated from the first source block of the pair and a second set of encoding symbols generated from the second source block of the pair, wherein the amount of encoding symbols in the first set is less than the amount of source data in the first source block and the amount of encoding symbols in the second set is less than the amount of source data in the second source block.

2. The method of claim 1, wherein the encoding process is such that, when the encoding symbols and the source symbols have the same size, when the first set of encoding symbols comprises M1 encoding symbols, the first source block comprises N1 source symbols, the second set of encoding symbols comprises M2 encoding symbols, the second source block comprises N2 source symbols, and when the intersection of the first and second source blocks comprises N3 source symbols with N3 is greater than zero, then recoverability of the union of the pair of source blocks is assured beyond a predetermined threshold probability if M1+M2=N1+N2−N3 for at least some combinations of values of M1<N1 and M2<N2.

3. The method of claim 2, wherein the recoverability of the union of the pair of source blocks is assured beyond a predetermined threshold probability if M1+M2=N1+N2−N3 for all combinations of values of M1 and M2 such that M1≦N1 and M2≦N2.

4. The method of claim 2, wherein the recoverability of the union of the pair of source blocks is certain if M1+M2=N1+N2−N3 for all combinations of values of M1 and M2 such that M1≦N1 and M2≦N2.

5. The method of claim 2, wherein recoverability of the union of the pair of source blocks is assured with a probability higher than a predetermined threshold probability if M1+M2 is larger than N1+N2−N3 by less than a predetermined percentage but smaller than N1+N2 for at least some combinations of values of M1 and M2.

6. The method of claim 1, wherein at least one encoding symbol generated from a source block is equal to a source symbol from the portion of the source data that is represented by that source block.

7. The method of claim 1, wherein the encoding is such that the portion of the source data that is represented by the first source block of the pair is assured to be recoverable from a third set of encoding symbols generated from the first source block, wherein the amount of encoding symbols in the third set is no greater than the amount of source data represented in the first source block.

8. The method of claim 1, wherein the encoding is such that the portion of the source data that is represented by the first source block of the pair is assured to be recoverable with a probability higher than a predetermined threshold probability from a third set of encoding symbols generated from the first source block, wherein the amount of encoding symbols in the third set is only slightly greater than the amount of source data represented in the first source block.

9. The method of claim 1, wherein the number of distinct encoding symbols that can be generated from each source block is independent of the size of the source block.

10. The method of claim 1, wherein the number of distinct encoding symbols that can be generated from each source block depends on the size of the source block.

11. The method of claim 1, wherein identifying base blocks for symbols is performed prior to a start to encoding.

12. The method of claim 1, wherein identifying source blocks for base blocks is performed prior to a start to encoding.

13. The method of claim 1, wherein at least one encoding symbol is generated before a base block is identified for each source symbol or before the enveloped base blocks are determined for each of the source blocks or before all of the source data is generated or made available.

14. The method of claim 1, further comprising:
receiving receiver feedback representing results at a decoder that is receiving or has received encoding symbols; and
adjusting one or more of membership of source symbols in base blocks, membership of base blocks in enveloping source blocks, number of source symbols per base block, number of symbols in a source block, and/or number of encoding symbols generated from a source block, wherein the adjusting is done based on, at least in part, the receiver feedback.

15. The method of claim 14, wherein adjusting includes determining new base blocks or changing membership of source symbols in previously determined base blocks.

16. The method of claim 14, wherein adjusting includes determining new source blocks or changing envelopment of base blocks for previously determined source blocks.

17. The method of claim 1, further comprising:
receiving data priority preference signals representing varying data priority preferences over the source data; and
adjusting one or more of membership of source symbols in base blocks, membership of base blocks in enveloping source blocks, number of source symbols per base block, number of symbols in a source block, and/or number of encoding symbols generated from a source block, wherein the adjusting is done based on, at least in part, the data priority preference signals.

18. The method of claim 1, wherein the number of source symbols in the base blocks enveloped by each source block is independent, as between two or more of the source blocks.

19. The method of claim 1, wherein source symbols identified to a base block are not consecutive within the ordered plurality of source symbols.

20. The method of claim 1, wherein the source symbols identified to a base block are consecutive within the ordered plurality of source symbols.

21. The method of claim 20, wherein source symbols identified to the base blocks enveloped by a source block are consecutive within the ordered plurality of source symbols.

22. The method of claim 1, wherein the number of encoding symbols that can be generated for a source block is independent of the number of encoding symbols that can be generated for other source blocks.

23. The method of claim 1, wherein the number of encoding symbols generated for a given source block is independent of the number of source symbols in the base blocks enveloped by the given source block.

24. The method of claim 1, wherein encoding comprises:
determining, for each encoding symbol, a set of coefficients selected from a finite field;
generating the encoding symbol as a combination of source symbols of one or more base blocks enveloped by a single source block, wherein the combination is defined, in part by the set of coefficients.

25. The method of claim 1, wherein the number of symbol operations to generate an encoding symbol from a source block is much less than the number of source symbols in the portion of the source data that is represented by the source block.

26. A method for decoding data received over a communications channel that could possibly include errors or erasures, to recover source data that was represented by a set of source symbols, the method comprising:
identifying a base block for each source symbol, wherein the identified base block is one of a plurality of base blocks that, collectively, cover the source data;
identifying, from a plurality of source blocks and for each base block, at least one source block that envelops that base block, wherein the plurality of source blocks includes at least one pair of source blocks that have a characteristic that there is at least one base block that is enveloped by both source blocks of the pair and at least one base block for each source block of the pair that is enveloped by that source block and not by the other source block of the pair; and
receiving a plurality of received symbols;
for each received symbol, identifying a source block for which that received symbols is an encoding symbol for; and
decoding a set of source symbols from the plurality of received symbols, wherein the portion of the source data that is represented by the union of the pair of source blocks is assured to be recoverable from a combination of a first set of received symbols corresponding to encoding symbols that were generated from the first source block of the pair and a second set of received symbols corresponding to encoding symbols that were generated from the second source block of the pair, wherein the amount of received symbols in the first set is less than the amount of source data in the first source block and the amount of received symbols in the second set is less than the amount of source data in the second source block.

27. The method of claim 26, wherein if N1 is the number of source symbols in the source data of the first source block, if N2 is the number of source symbols in the source data of the second source block, if N3 is the number of source symbols in the intersection of the first and second source blocks with N3 greater than zero, if the encoding symbols and the source symbols have the same size, if R1 is the number of received symbols in the first set of received symbols, if R2 is the number of received symbols in the second set of received symbols, then decoding the union of the pair of source blocks from the first set of R1 received symbols and from the second set of R2 received symbols is assured beyond a predetermined threshold probability if R1+R2=N1+N2−N3, for at least one value of R1 and R2 such that R1<N1 and R2<N2.

28. The method of claim 27, wherein decoding the union of the pair of source blocks is assured beyond a predetermined threshold probability if R1+R2=N1+N2−N3 for all values of R1≦N1 and R2≦N2.

29. The method of claim 27, wherein decoding the union of the pair of source blocks is certain if R1+R2=N1+N2−N3 for all values of R1≦N1 and R2≦N2.

30. The method of claim 26, wherein the portion of the source data that is represented by the first source block of the pair is recoverable from a third set of encoding symbols generated from the first source block, wherein the amount of encoding symbols in the third set is no greater than the amount of source data represented in the first source block.

31. The method of claim 26, wherein the number of distinct encoding symbols that can be generated from each source block is independent of the size of the source block.

32. The method of claim 26, wherein at least one of identifying base blocks for source symbols and identifying source blocks for base blocks is performed prior to a start to encoding.

33. The method of claim 26, wherein at least some encoding symbols are generated before a base block is identified for each source symbol and/or before the enveloped base blocks are determined for each of the source blocks.

34. The method of claim 26, further comprising:
determining receiver feedback representing results at a decoder based on what received symbols have been received and/or what portion of the source data is desired at a receiver and/or data priority preference; and
outputting the receiver feedback such that it is usable for altering an encoding process.

35. The method of claim 26, wherein the number of source symbols in the base blocks enveloped by each source block is independent, as between two or more of the source blocks.

36. The method of claim 26, wherein the source symbols identified to a base block are consecutive within the ordered plurality of source symbols.

37. The method of claim 26, wherein source symbols identified to the base blocks enveloped by a source block are consecutive within the ordered plurality of source symbols.

38. The method of claim 26, wherein decoding further comprises:
determining, for each received symbol, a set of coefficients selected from a finite field; and
decoding at least one source symbol from more than one received symbol or previously decoded source symbols using the set of coefficients for the more than one received symbol.

39. The method of claim 26, wherein the number of symbol operations to recover a union of one or more source blocks is much less than the square of the number of source symbols in the portion of the source data that is represented by the union of the source blocks.

40. An encoder that encodes data for transmission over a communications channel that could possibly introduce errors or erasures, comprising:
an input for receiving source data that is represented by an ordered plurality of source symbols and the source data is recoverable from encoding symbols that are transmitted;
storage for at least a portion of a plurality of base blocks, wherein each base block comprises a representation of one or more source symbol of the ordered plurality of source symbols;
a logical map, stored in a machine-readable form or generatable according to logic instructions, mapping each of a plurality of source blocks to one or more base block, wherein the plurality of source blocks includes at least one pair of source blocks that have a characteristic that there is at least one base block that is enveloped by both source blocks of the pair and at least one base block for each source block of the pair that is enveloped by that source block and not by the other source block of the pair;
storage for encoded blocks; and
one or more encoders that each encode source symbols of a source block to form a plurality of encoding symbols, with a given encoding symbol being independent of source symbol values from source blocks other than the source block it encodes source symbols of, such that the portion of the source data that is represented by the union of the pair of source blocks is assured to be recoverable from a combination of a first set of encoding symbols generated from the first source block of the pair and a second set of encoding symbols generated from the second source block of the pair, wherein the amount of encoding symbols in the first set is less than the amount of source data in the first source block and the amount of encoding symbols in the second set is less than the amount of source data in the second source block.

41. The encoder of claim 40, wherein the number of encoding symbols in the first set plus the number of encoding symbols in the second set is no greater than the number of source symbols in the portion of the source data that is represented by the union of the pair of source blocks, if the encoding symbols and the source symbols have the same size.

42. The encoder of claim 40, wherein the portion of the source data that is represented by the first source block of the pair is recoverable from a third set of encoding symbols generated from the first source block, wherein the amount of encoding symbols in the third set is no greater than the amount of source data represented in the first source block.

43. The encoder of claim 40, wherein the number of distinct encoding symbols that can be generated from each source block is independent of the size of the source block.

44. The encoder of claim 40, further comprising:
an input for receiving receiver feedback representing results at a decoder that is receiving or has received encoding symbols; and
logic for adjusting one or more of membership of source symbols in base blocks, membership of base blocks in enveloping source blocks, number of source symbols per base block, number of symbols in a source block, and/or number of encoding symbols generated from a source block, wherein the adjusting is done based on, at least in part, the receiver feedback.

45. The encoder of claim 40, further comprising:
an input for receiving data priority preference signals representing varying data priority preferences over the source data; and
logic for adjusting one or more of membership of source symbols in base blocks, membership of base blocks in enveloping source blocks, number of source symbols per base block, number of symbols in a source block, and/or number of encoding symbols generated from a source block, wherein the adjusting is done based on, at least in part, the data priority preference signals.

46. The encoder of claim 40, wherein the number of source symbols in the base blocks enveloped by each source block is independent, as between two or more of the source blocks.

47. The encoder of claim 40, wherein the source symbols identified to a base block are consecutive within the ordered plurality of source symbols.

48. The encoder of claim 40, wherein source symbols identified to the base blocks enveloped by a source block are consecutive within the ordered plurality of source symbols.

49. The encoder of claim 40, wherein the number of distinct encoding symbols that can be generated for a source block is independent of the number of encoding symbols that can be generated for other source blocks.

50. The encoder of claim 40, wherein the number of distinct encoding symbols generated for a given source block is independent of the number of source symbols in the base blocks enveloped by the given source block.

51. The encoder of claim 40, further comprising:
storage for a set of coefficients selected from a finite field for each of a plurality of the encoding symbols; and
logic for generating the encoding symbol as a combination of source symbols of one or more base blocks enveloped by a single source block, wherein the combination is defined, in part by the set of coefficients.
